(19) United States
(12) Patent Application Publication
(10) Pub. No.: US 2024/0310952 A1
(43) Pub. Date: Sep. 19, 2024

(54) DISPLAY DEVICE

(71) Applicant: SAMSUNG DISPLAY CO., LTD., YONGIN-SI (KR)

(72) Inventors: GEE BUM KIM, Yongin-si (KR); BO KWANG SONG, Yongin-si (KR); KWANG SOO BAE, Yongin-si (KR); DAE YOUNG LEE, Yongin-si (KR); MIN OH CHOI, Yongin-si (KR)

(21) Appl. No.: 18/527,489

(22) Filed: Dec. 4, 2023

(30) Foreign Application Priority Data
Mar. 13, 2023 (KR) 10-2023-0032740

(51) Int. Cl. G06F 3/041; G06F 3/044; G06V 40/13

(52) U.S. Cl. CPC G06F 3/0418; G06F 3/0412; G06F 3/0446; G06V 40/1306; G06F 2203/04111; G06F 2203/04112; G09G 3/3233; G09G 2300/0426; G09G 2300/0842; G09G 2354/00

(57) ABSTRACT

A display device includes unit pixels, each unit pixel including display pixels and a light sensing pixel, touch electrodes sensing a touch and, when viewed in a plan view, surrounding a first region where each of at least two display pixels is disposed and a second region where the light sensing pixel and one of the display pixels that is different from the at least two display pixels are disposed, and a main driving circuit receiving a light sensing signal from the light sensing pixel and sensing a fingerprint by analyzing the light sensing signal. The touch electrodes define at least one open area in which no touch electrode is formed between the light sensing pixel and at least one display pixel in each unit pixel.

### CROSS-REFERENCE TO RELATED APPLICATION

This application claims priority from Korean Patent Application No. 10-2023-0032740 filed on Mar. 13, 2023 in the Korean Intellectual Property Office, and all the benefits accruing therefrom under 35 U.S.C. 119, the contents of which in its entirety are herein incorporated by reference.

### BACKGROUND

### 1. Technical Field

The present disclosure relates to a display device.

### 2. Discussion of Related Art

As the information-oriented society evolves, various demands for display devices are ever increasing. Various electronic devices such as smart phones, digital cameras, laptop computers, table PCs, navigation devices, and smart televisions may employ display devices.

As the mobile communications technology evolves, portable electronic devices such as smartphones, tablet PCs and laptop computers are prevailing. Privacy information is stored in portable electronic devices. Accordingly, in order to protect such privacy information stored in portable electronic devices, fingerprint authentication is desirable to authenticate biometric information such as a user's fingerprint.

For example, a display device may recognize and authenticate a user's fingerprint in an optical, ultrasonic, or capacitive sensing technology. The optical sensing may authenticate a user's fingerprint by sensing light reflected by a user's fingerprint.

### SUMMARY

Aspects of the present disclosure provide a display device capable of reducing noise due to reflected light by preventing touch electrodes from being cut or formed between each photo-sensing pixel and at least one adjacent image display pixel.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an embodiment of the present disclosure, a display device includes a plurality of unit pixels, wherein each unit pixel of the plurality of unit pixels includes a plurality of display pixels emitting respective lights and a light sensing pixel sensing light that is received from a front surface of the display device, a plurality of touch electrodes configured to sense a touch on the front surface and, when viewed in a plan view, surrounding a first region where each of at least two display pixels is disposed and a second region where the light sensing pixel and one of the plurality of display pixels that is different from the at least two display pixels are disposed, and a main driving circuit configured to receive a light sensing signal from the light sensing pixel and sense a fingerprint by analyzing the light sensing signal. The plurality of touch electrodes define at least one open area in which no touch electrode is formed between the light sensing pixel and at least one display pixel among the plurality of display pixels in each unit pixel of the plurality of unit pixels.

In an embodiment, the plurality of display pixels comprise first to third display pixels, the first to third display pixels comprise first to third emission areas, respectively, and the light sensing pixel comprises light sensing area, and the at least one open area corresponds to a space between the light sensing area and an emission area of the at least one display pixel in each unit pixel of the plurality of unit pixels.

In an embodiment, the first to third emission areas and the light sensing area are arranged in a horizontal structure, in a vertical stripe structure, or in a Pentile™ matrix structure, the plurality of touch electrodes comprise a plurality of driving electrodes, a plurality of sensing electrodes, and a plurality of dummy electrodes, and the plurality of driving electrodes, the plurality of sensing electrodes, and the plurality of dummy electrodes are formed in a mesh structure surrounding each of the first to third emission areas.

In an embodiment, at least one electrode of the plurality of driving electrodes, the plurality of sensing electrodes, and the plurality of dummy electrodes defines the at least one open area that corresponds to a space between the light sensing area and at least one emission area among the first to third emission areas in each unit pixel of the plurality of unit pixels.

In an embodiment, at least one electrode of the plurality of driving electrodes, the plurality of sensing electrodes, and the plurality of dummy electrodes is formed in a mesh structure when viewed in a plan view, the at least one open area corresponds to a space between the light sensing area of the light sensing pixel and an emission area of a second display pixel among the first to third display pixels, the second display pixel and the light sensing pixel are disposed in the second region, and the emission area of the second display pixel displays green light.

In an embodiment, the second display pixel is driven to emit the green light during a fingerprint sensing period, and the light sensing pixel is driven to sense light that is incident on the light sensing area from the front surface of the display device.

In an embodiment, at least one electrode of the plurality of driving electrodes, the plurality of sensing electrodes, and the plurality of dummy electrodes is formed in a mesh structure when viewed in a plan view, the at least one open area corresponds to a space between the light sensing area of the light sensing pixel and an emission area of the first display pixel among the first to third display pixels, the first display pixel and the light sensing pixel are disposed in the second region, and the emission area of the first display pixel displays red light.

In an embodiment, the first display pixel is driven to emit the red light during a fingerprint sensing period, and the light sensing pixel is driven to sense light that is incident on the light sensing area from the front surface of the display device.

In an embodiment, at least one electrode of the plurality of driving electrodes, the plurality of sensing electrodes, and the plurality of dummy electrodes is formed in a mesh structure when viewed in a plan view, the at least one open area corresponds to a space between the light sensing area of the light sensing pixel and an emission area of the third display pixel among the first to third display pixels, the third display pixel and the light sensing pixel are disposed in the second region, and the emission area of the third display pixel displays blue light.

In an embodiment, the third display pixel is driven to emit the blue light during a fingerprint sensing period, and the light sensing pixel is driven to sense light that is incident on the light sensing area from the front surface of the display device.

According to an embodiment of the present disclosure, a display device includes a plurality of unit pixels arranged in a horizontal stripe structure, in a vertical stripe structure, or in a Pentile™ matrix structure, wherein each unit pixel of the plurality of unit pixels includes first to third display pixels and a light sensing pixel, a plurality of touch electrodes disposed over the first to third display pixels and the light sensing pixel to sense a touch, and a main driving circuit for receiving a light sensing signal from the light sensing pixel to sense a fingerprint. The plurality of touch electrodes define at least one open area in which no touch electrode is formed in each unit pixel of the plurality of unit pixels. When viewed in a plan view, the at least one open area corresponds to a space between the light sensing pixel and at least one display pixel among the first to third display pixels in a region where each unit pixel of the plurality of unit pixels is formed.

In an embodiment, the first to third display pixels comprise first to third emission areas, respectively, the light sensing pixel comprises a light sensing area, the plurality of touch electrodes comprise a plurality of driving electrodes, a plurality of sensing electrodes, and a plurality of dummy electrodes, and the plurality of driving electrodes, the plurality of sensing electrodes, and the plurality of dummy electrodes are formed in a mesh structure surrounding the light sensing area.

In an embodiment, at least one electrode of the plurality of driving electrodes, the plurality of sensing electrodes, and the plurality of dummy electrodes defines the at least one open area that corresponds to a space between the light sensing area and at least one emission area among the first to third emission areas in each unit pixel of the plurality of unit pixels.

In an embodiment, the at least one open area corresponds to a space between the light sensing area and the second display pixel among the first to third display pixels, and the emission area of the second display pixel displays green light.

In an embodiment, the second display pixel is driven to emit the green light during a fingerprint sensing period, and the light sensing pixel is driven to sense light that is incident on the light sensing area from a front surface of the display device.

According to an embodiment of the present disclosure, a display device may reduce noise due to reflected light and improve fingerprint sensing accuracy by preventing touch electrodes from being cut or formed between each of the photo-sensing pixels and image display pixels.

However, the effects of the present disclosure are not limited to the aforementioned effects, and various other effects are included in the present disclosure.

### BRIEF DESCRIPTION OF THE DRAWINGS

The above and other aspects and features of the present disclosure will become more apparent by describing in detail embodiments thereof with reference to the attached drawings, in which:

FIG. 1 is a perspective view of a display device according to an embodiment of the present disclosure;

FIG. 2 is a plan view illustrating a layout structure of a display panel and a display driving circuit as illustrated in FIG. 1 according to an embodiment of the present disclosure;

FIG. 3 is a plan view illustrating a layout structure of a display panel and a display driving circuit according to an embodiment of the present disclosure;

FIG. 4 is a side view of a display device according to an embodiment of the present disclosure;

FIG. 5 is a layout diagram of the display panel as illustrated in FIGS. 1 to 4 according to an embodiment of the present disclosure;

FIG. 6 is a layout diagram of a display area according to an embodiment of the present disclosure;

FIG. 7 is a circuit diagram of a display pixel and a light sensing pixel according to an embodiment of the present disclosure;

FIG. 8 is a layout diagram of a touch sensing unit as illustrated in FIG. 4 according to an embodiment of the present disclosure;

FIG. 9 is an enlarged view of area A1 of FIG. 8 according to an embodiment of the present disclosure;

FIG. 10 is an enlarged view of area A1 of FIG. 8 according to an embodiment of the present disclosure of the present disclosure;

FIG. 11 is an enlarged view of area A1 of FIG. 8 according to an embodiment of the present disclosure;

FIG. 12 is an enlarged view of area A1 of FIG. 8 according to an embodiment of the present disclosure;

FIG. 13 is a cross-sectional view of a cross section I-I′ of FIG. 9 according to an embodiment of the present disclosure;

FIGS. 14 and 15 are perspective views of a display device according to an embodiment of the present disclosure; and

FIGS. 16 and 17 are perspective views of a display device according to an embodiment of the present disclosure.

### DETAILED DESCRIPTION OF THE EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the present invention. The second element may also be termed the first element.

Each of the features of the various embodiments of the present disclosure may be combined or combined with each other, in part or in whole, and technically various interlocking and driving are possible. Each embodiment may be implemented independently of each other or may be implemented together in an association.

Hereinafter, specific embodiments will be described with reference to the accompanying drawings.

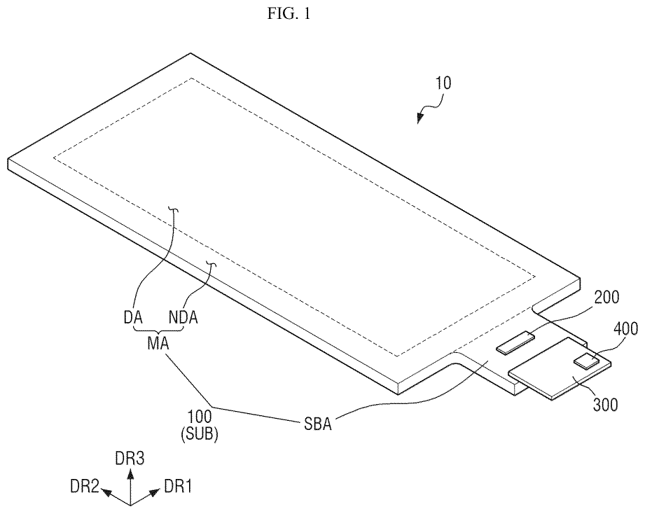

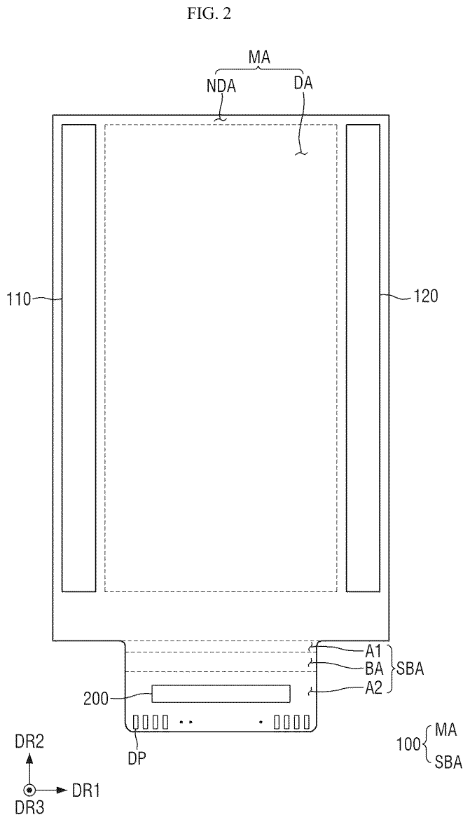

FIG. 1 is a perspective view illustrating a display device according to an embodiment. FIG. 2 is a plan view illustrating a layout structure of a display panel and a display driving circuit illustrated in FIG. 1.

Referring to FIGS. 1 and 2, a display device 10 according to an embodiment may be applied to portable electronic devices such as mobile phones, smartphones, tablet personal computers (PCs), mobile communication terminals, electronic notebooks, electronic books, portable multimedia players (PMPs), navigation devices, and ultra mobile PCs (UMPCs). The display device 10 according to an embodiment may be applied as a display unit of televisions, laptop computers, monitors, billboards, or the Internet of Things (IOTs). The display device 10 according to an embodiment may be applied to wearable devices such as smart watches, watch phones, glasses-type displays, and head mounted displays (HMDs). The display device 10 according to an embodiment may be applied to a center information display (CID) disposed on an instrument board, a center fascia, or a dashboard of a vehicle or a display disposed on a rear surface of a front seat as entertainment for a rear seat of the vehicle.

The display device 10 may be a light emitting display device such as an organic light emitting display device using an organic light emitting diode, a quantum dot light emitting display device including a quantum dot light emitting layer, an inorganic light emitting display device including an inorganic semiconductor, and a micro light emitting display device using a micro or nano light emitting diode (micro LED or nano LED). Hereinafter, it will be mainly described that the display device 10 is the organic light emitting display device, but the present disclosure is not limited thereto.

A display panel 100 may have a rectangular shape, when viewed in a plan view. For example, the display panel 100 may have shorter sides extending in a first direction DR1 and longer sides extending in a second direction DR2 crossing the first direction DR1. A corner where the short side in the first direction DR1 and the long side in the second direction DR2 meet may be right-angled or rounded with a predetermined curvature. The shape of the display panel 100 when viewed in a plan view is not limited to the rectangular shape, and may be other polygonal shapes, a circular shape, or an elliptical shape. The display panel 100 may be formed to be flat, but is not limited thereto. For example, the display panel 100 may include curved surface parts formed at left and right ends thereof and having a constant curvature or a variable curvature. The display panel 100 may be flexible. For example, the display panel 100 may be curved, bent, folded, or rolled in a manufacturing process of the display panel 100 or by a user for use.

A substrate SUB of the display panel 100 may be divided into a main area MA and a sub-area SBA.

The main area MA may be divided into a display area DA displaying an image and a non-display area NDA, which is a peripheral area of the display area DA.

The non-display area NDA may be adjacent to the display area DA. The non-display area NDA may be an area outside the display area DA. The non-display area NDA may surround the display area DA. The non-display area NDA may be an edge area of the display panel 100.

The display area DA includes display pixels displaying an image and light sensing pixels sensing light reflected on a protective cover, a protective glass of a front surface, and a user's body part such as a finger. The display area DA may occupy most of the main area MA. The display area DA may be disposed at the center of the main area MA.

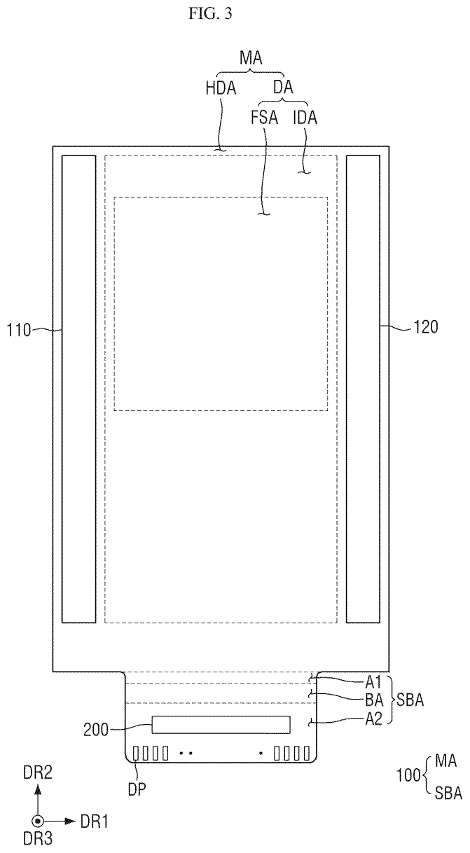

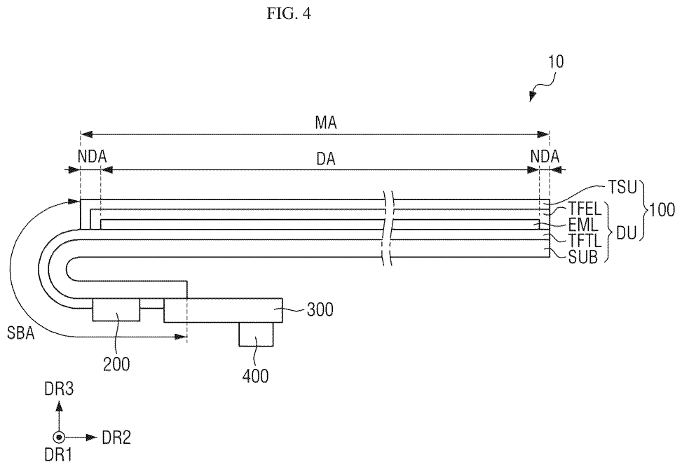

FIG. 3 is a plan view illustrating a layout structure of a display panel and a display driving circuit according to an embodiment. FIG. 4 is a side view illustrating the display device according to an embodiment.

Referring to FIG. 3, the display area DA may be divided into an image display area IDA in which the light sensing pixels are not present and only the display pixels are disposed and a reflected light sensing area FSA in which both the display pixels and the light sensing pixels LSP are present for sensing a fingerprint. For example, the light sensing pixels formed in order to sense a fingerprint may be disposed together with the display pixels only in the reflected light sensing area FSA, which is a preset portion of the entire display area DA of the display panel 100. However, an example in which the display pixels and the light sensing pixels are alternately arranged in the entire area of the display area DA will hereinafter be described.

The sub-area SBA may protrude from one side of the main area MA in the second direction DR2. A length of the sub-area SBA in the second direction DR2 may be smaller than the length of the main area MA in the second direction DR2. A length of the sub-area SBA in the first direction DR1 may be smaller than or substantially the same as a length of the main area MA in the first direction DR1.

The sub-area SBA may include a first area A1, a second area A2, and a bending area BA.

The first area A1 is an area protruding from one side of the main area MA in the second direction DR2. One side of the first area A1 may contact the non-display area NDA of the main area MA, and the other side of the first area A1 may contact the bending area BA. The term “contact,” as used herein, refers to a direct connection (i.e., physical touching) unless the context indicates otherwise.

The second area A2 is an area in which pads DP and a main driving circuit 200 are disposed. The main driving circuit 200 may be attached to driving pads of the second area A2 using a conductive adhesive member such as an anisotropic conductive film. A circuit board 300 may be attached to the pads DP of the second area A2 using a conductive adhesive member. One side of the second area A2 may contact the bending area BA.

The bending area BA is an area that is bent. When the bending area BA is bent, the second area A2 may be disposed below the first area A1 and below the main area MA. The bending area BA may be disposed between the first area A1 and the second area A2. One side of the bending area BA may contact the first area A1, and the other side of the bending area BA may contact the second area A2.

As illustrated in FIG. 4, the sub-area SBA may be bent, and the sub-area SBA may be disposed below the main area MA. The sub-area SBA may overlap the main area MA in a third direction DR3.

A touch sensing unit TSU sensing a touch position of a body part such as a finger may be disposed on a front surface of the display panel 100 including the display area DA. The touch sensing unit TSU may include a plurality of touch electrodes to sense a user's touch in a capacitive manner.

The touch sensing unit TSU includes the plurality of touch electrodes that are arranged to cross each other in the first and second directions DR1 and DR2. For example, the plurality of touch electrodes may be formed to extend in a line area between the display pixels and the light sensing pixels (or an image non-display area in which lines are formed) so as not to overlap the respective display pixels and light sensing pixels arranged in the display area DA. The plurality of touch electrodes form mutual capacitance and transmit touch sensing signals that vary according to the user's touch to a touch sensing circuit 400.

The touch sensing circuit 400 may sense changes in mutual capacitance between the respective touch electrodes input from the plurality of touch electrodes, and supply touch data according to the changes in mutual capacitance, coordinate data of a position where the touch is sensed, and the like, to the main driving circuit 200.

The circuit board 300 may be attached to one end of the sub-area SBA. The touch sensing circuit 400 may be mounted on the circuit board 300 and electrically connected to the touch electrodes of the touch sensing unit TSU. The circuit board 300 may be electrically connected to the display panel 100 and the main driving circuit 200. The display panel 100 and the main driving circuit 200 may receive digital video data, timing signals, and driving voltages through the circuit board 300. The circuit board 300 may be a flexible printed circuit board, a printed circuit board, or a flexible film such as a chip on film.

The main driving circuit 200 may generate digital data and electrical control signals for driving the display panel 100. Each of the main driving circuit 200 and the touch sensing circuit 400 may be formed as an integrated circuit (IC). Each of the main driving circuit 200 and the touch sensing circuit 400 may be attached onto the display panel 100 or the circuit board 300 in a chip on glass (COG) manner, a chip on plastic (COP) manner, or an ultrasonic bonding manner, but is not limited thereto. For example, the main driving circuit 200 and the touch sensing circuit 400 may be attached onto the circuit board 300 in a chip on film (COF) manner.

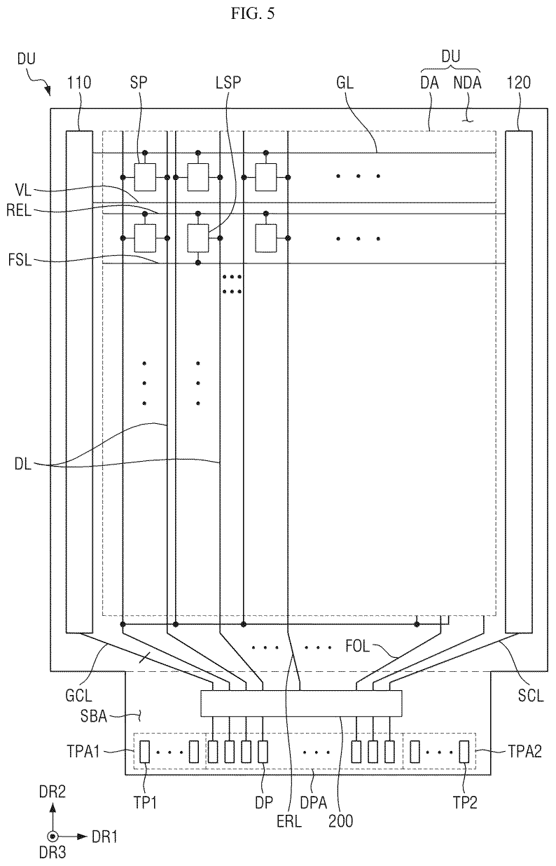

FIG. 5 is a layout diagram of the display panel as illustrated in FIGS. 1 to 4 according to an embodiment of the present disclosure. FIG. 5 is a layout diagram illustrating a display area DA and a non-display area NDA of a display module DU in a state before the touch sensing unit TSU is formed.

Referring to FIG. 5 together with FIG. 4, a display scan driver 110, a light sensing scan driver 120, and the main driving circuit 200 may be disposed in the display panel 100 of the display device 10 according to an embodiment. The touch sensing circuit 400, a power supply unit (not illustrated), and the like, may be disposed on the circuit board 300 connected to the display panel 100. Here, both the main driving circuit 200 and the touch sensing circuit 400 may be integrally formed as a single chip and may be mounted on the display panel 100 or the circuit board 300. The present invention is not limited thereto. In some embodiments, the main driving circuit 200 and the touch sensing circuit 400 are formed in different chips as shown in FIG. 4.

Referring to FIG. 5, the display panel 100 may include display pixels SP, light sensing pixels LSP, display scan lines GL, emission control lines VL, data lines DL, light sensing scan lines FSL, sensing reset lines REL, and light sensing lines ERL that are disposed in the display area DA. Each of the display scan driver 110 and the light sensing scan driver 120 is disposed in the non-display area NDA.

The display scan lines GL sequentially supply display scan signals applied in units of each horizontal line from the display scan driver 110 to a plurality of display pixels SP for each horizontal line. The display scan lines GL may extend in the first direction DR1 and may be spaced apart from each other in the second direction DR2 crossing the first direction DR1.

The emission control lines VL sequentially supply emission control signals applied in units of each horizontal line from the display scan driver 110 to the plurality of display pixels SP for each horizontal line. The emission control lines VL may extend in the first direction DR1 in parallel with the display scan lines GL and may be spaced apart from each other in the second direction DR2 crossing the first direction DR1.

The data lines DL may supply data voltages received from the main driving circuit 200 to the plurality of display pixels SP. A plurality of data lines DL may extend in the second direction DR2 and may be spaced apart from each other in the first direction DR1.

The light sensing scan lines FSL sequentially supply sensing scan signals applied in units of each horizontal line from the light sensing scan driver 120 to a plurality of light sensing pixels LSP. The light sensing scan lines FSL may extend in the first direction DR1 and may be spaced apart from each other in the second direction DR2 crossing the first direction DR1.

The sensing reset lines REL sequentially supply sensing reset signals applied in units of each horizontal line from the light sensing scan driver 120 to the plurality of light sensing pixels LSP for each horizontal line. The sensing reset lines REL may extend in the first direction DR1 in parallel with the light sensing scan lines FSL and may be spaced apart from each other in the second direction DR2 crossing the first direction DR1.

The light sensing lines ERL are connected between the respective light sensing pixels LSP and the main driving circuit 200 to supply light sensing signals output from the respective light sensing pixels LSP to the main driving circuit 200. The light sensing lines ERL may be disposed and extended in the second direction DR2 according to a direction in which the main driving circuit 200 is disposed and may be spaced apart from each other in the first direction DR1.

The non-display area NDA may surround the display area DA. The non-display area NDA may include the display scan driver 110, the light sensing scan driver 120, fan-out lines FOL, gate control lines GCL, and light sensing control lines SCL.

The display pixels SP and the light sensing pixels LSP may be arranged in a matrix form in the first direction DR1 and the second direction DR2 in the display area DA. For example, three display pixels SP displaying red light, green light, and blue light, respectively, and one light sensing pixel LSP may constitute one unit pixel. For example, a plurality of unit pixels may be periodically arranged in the display area DA in the first and second direction DR1 and DR2. The red, green, and blue display pixels SP and the light sensing pixels LSP constituting each unit pixel may be alternately arranged in a horizontal or vertical stripe form. Each of the red, green, and blue display pixels SP may be connected to one of the display scan lines GL and one of the emission control lines VL. The respective display pixels SP may receive the data voltages of the data lines DL according to the display scan signals of the display scan lines GL and the emission control signals of the emission control lines VL and supply driving currents to light emitting elements according to the data voltages to emit light.

The light sensing pixels LSP may be arranged alternately with the red, green, and blue display pixels SP in a vertical or horizontal direction. Each of the light sensing pixels LSP may be connected to one of the light sensing scan lines FSL, one of the sensing reset lines REL, and one of the light sensing lines ERL. The respective light sensing pixels LSP may be reset in response to the sensing reset signals from the sensing reset lines REL, and may generate light sensing signals corresponding to an amount of reflected light incident from a front direction. The respective light sensing pixels LSP may transmit the light sensing signals to the light sensing lines ERL in response to the sensing scan signals from the light sensing scan lines FSL.

In some embodiments, each of the light sensing pixels LSP may be connected to one of the display scan lines GL in units of horizontal lines. The respective light sensing pixels LSP may generate light sensing signals corresponding to the amount of reflected light incident from the front direction, and output the light sensing signals to the light sensing lines ERL in response to the display scan signals input through the display scan lines GL.

The display scan driver 110 may be disposed in the non-display area NDA. The display scan driver 110 is disposed on one side (e.g., the left side) of the display panel 100, but the present disclosure is not limited to that illustrated in the drawing. For example, the display scan drivers 110 may be disposed on opposite sides (e.g., left and right sides) of the display panel 100.

The display scan driver 110 may be electrically connected to the main driving circuit 200 through the gate control lines GCL. The display scan driver 110 receives scan control signals from the main driving circuit 200, sequentially generates display scan signals in units of horizontal line driving periods according to the scan control signals, and sequentially supplies the display scan signals to the display scan lines GL. The display scan driver 110 may sequentially generate emission control signals according to the scan control signals from the main driving circuit 200 and sequentially supply the emission control signals to the emission control lines VL.

The gate control lines GCL may extend from the main driving circuit 200 to the display scan driver 110 according to a position where the display scan driver 110 is disposed. The gate control lines GCL may supply the scan control signals received from the main driving circuit 200 to the display scan driver 110.

The light sensing scan driver 120 may be disposed in a non-display area NDA. In some embodiments, the light sensing scan driver 120 may be disposed in a portion of the non-display area NDA opposite to a portion thereof in which the display scan driver 110 is disposed. For example, the light sensing scan driver 120 is disposed to the right side of the display panel 100, and the display scan driver 110 is disposed to the left side of the display panel 100. The present disclosure, however, is not limited thereto. The light sensing scan driver 120 may be electrically connected to the main driving circuit 200 through the light sensing control lines SCL. The light sensing scan driver 120 receives light sensing control signals from the main driving circuit 200 and sequentially generates reset control signals and sensing scan signals in units of horizontal line driving periods according to the light sensing control signals. The light sensing scan driver 120 sequentially supplies the sequentially generated reset control signals to the sensing reset lines REL. The light sensing scan driver 120 may sequentially generate the sensing scan signals according to the light sensing control signals from the main driving circuit 200 and sequentially supply the sensing scan signals to the light sensing scan lines FSL.

The light sensing control lines SCL may extend from the main driving circuit 200 to the light sensing scan driver 120 according to a position where the light sensing scan driver 120 is disposed. The light sensing control lines SCL may supply the light sensing control signals received from the main driving circuit 200 to the light sensing scan driver 120.

The sub-area SBA may include the main driving circuit 200, a display pad area DPA, and first and second touch pad areas TPA1 and TPA2. The display pad area DPA, the first touch pad area TPA1, and the second touch pad area TPA2 may be disposed at an edge of the sub-area SBA. The display pad area DPA, the first touch pad area TPA1, and the second touch pad area TPA2 may be electrically connected to the circuit board 300 using an anisotropic conductive layer or a low-resistance high-reliability material such as a self-assembly anisotropic conductive paste (SAP).

The fan-out lines FOL may extend from the main driving circuit 200 to the display area DA. The fan-out lines FOL are connected to the main driving circuit 200 and the plurality of data lines DL so that the data voltages received from the main driving circuit 200 may be supplied to the plurality of data lines DL, respectively.

The main driving circuit 200 may output signals and voltages for driving the display panel 100 to the fan-out lines FOL. The main driving circuit 200 may supply the data voltages to the data lines DL through the fan-out lines FOL. The data voltages may be supplied to the plurality of display pixels SP, and may determine luminance of the display pixels SP. The main driving circuit 200 may supply the scan control signals to the display scan driver 110 through the gate control lines GCL. The main driving circuit 200 may generate digital video data according to touch coordinates according to touch coordinate data from the touch sensing circuit 400 or execute an application indicated by an icon displayed at user's touch coordinates.

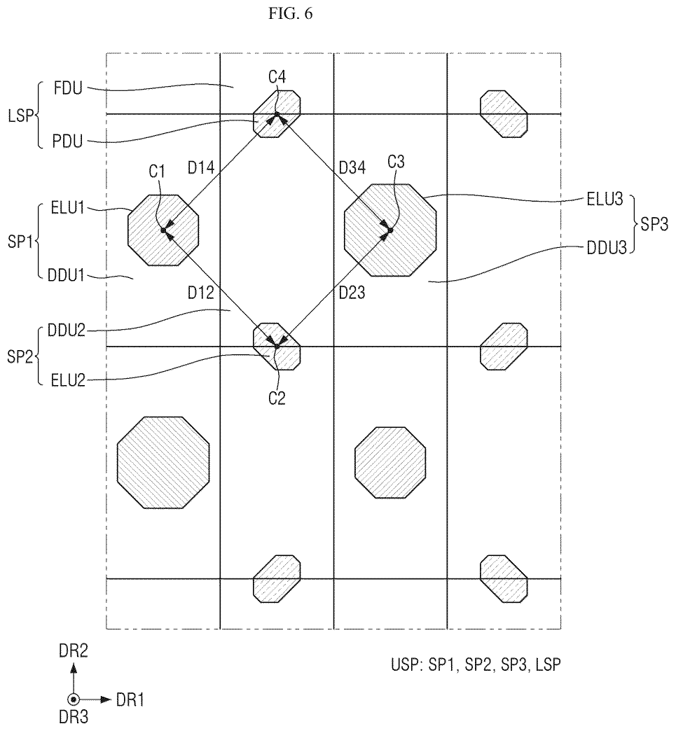

FIG. 6 is a layout diagram of a display area according to an embodiment of the present disclosure.

Referring to FIG. 6, the display area DA may include first display pixels SP1, second display pixels SP2, third display pixels SP3, and light sensing pixels LSP. In some embodiment, one of the first display pixels SP1, one of the second display pixels SP2, one of the third display pixels SP3, and one of the light sensing pixels LSP may constitute a unit pixel which is periodically repeated in the display area DA in the first and second directions DR1 and DR2. The display pixels SP may include the first display pixels SP1, the second display pixels SP2, and the third display pixels SP3. The light sensing pixel LSP with the first display pixel SP1, the second display pixel SP2, and the third display pixel SP3 may constitute a unit pixel USP. The unit pixel USP may be defined as a minimum unit of display pixels capable of sensing light while displaying white.

The first display pixel SP1 may include a first light emitting unit ELU1 emitting first light and a first pixel driving unit DDU1 for applying a driving current to a light emitting element of the first light emitting unit ELU1. The first light may be light of a red wavelength band. For example, a main peak wavelength of the first light may be positioned between approximately 600 nm and approximately 750 nm.

The second display pixel SP2 may include a second light emitting unit ELU2 emitting second light and a second pixel driving unit DDU2 for applying a driving current to a light emitting element of the second light emitting unit ELU2. The second light may be light of a green wavelength band. For example, a main peak wavelength of the second light may be positioned between approximately 370 nm and approximately 460 nm.

The third display pixel SP3 may include a third light emitting unit ELU3 emitting third light and a third pixel driving unit DDU3 for applying a driving current to a light emitting element of the third light emitting unit ELU3. The third light may be light of a blue wavelength band. For example, a main peak wavelength of the third light may be positioned between approximately 480 nm and approximately 560 nm.

The light sensing pixel LSP includes light sensing unit PDU and sensing driving unit FDU.

In the unit pixel USP, the first to third pixel driving units DDU1 to DDU3 may be disposed according to a preset order in the first direction DR1. In some embodiments, any one pixel driving unit of the first to third pixel driving units DDU1 to DDU3 may be disposed in the first direction DR1 with other adjacent pixel driving units. The sensing driving unit FDU may be disposed in the first direction DR1 of any one pixel driving unit of the first to third pixel driving units DDU1 to DDU3. In some embodiments, the sensing driving unit FDU may be disposed in the second direction DR2 of any one pixel driving unit of the first to third pixel driving units DDU1 to DDU3.

The first pixel driving unit DDU1 may be adjacent to each other in the second direction DR2 along which the data line DL extends as shown in FIG. 5. The second pixel driving units DDU2 may be adjacent to each other in the second direction DR2. The sensing driving units FDU be adjacent to each other in the second direction DR2.

The first light emitting unit ELU1, the second light emitting unit ELU2, the third light emitting unit ELU3, and the light sensing unit PDU may have a quadrilateral, octagonal, or rhombus planar shape, but are not limited thereto. The first light emitting unit ELU1, the second light emitting unit ELU2, the third light emitting unit ELU3, and the light sensing unit PDU may have a polygonal planar shape other than a quadrangle, an octagon, and a rhombus.

Due to positions where the first light emitting unit ELU1, the second light emitting unit ELU2, the third light emitting unit ELU3, and the light sensing unit PDU are disposed and shapes of the first light emitting unit ELU1, the second light emitting unit ELU2, the third light emitting unit ELU3, the light sensing unit PDU when viewed in a plan view, a distance D12 between the center C1 of the first light emitting unit ELU1 and the center C2 of the second light emitting unit ELU2 neighboring to each other in a first diagonal direction between the first and second directions DR1 and D2, a distance D23 between the center C2 of the second light emitting unit ELU2 and the center C3 of the third light emitting unit ELU3 neighboring to each other in a second diagonal direction crossing the first diagonal direction, a distance D14 between the center C1 of the first light emitting unit ELU1 and the center C4 of the light sensing unit PDU neighboring to each other in a third diagonal direction parallel to the second diagonal direction, and a distance D34 between the center C3 of the third light emitting unit ELU3 and the center C4 of the light sensing unit PDU neighboring to each other in a fourth diagonal direction parallel to the first diagonal direction may be substantially the same as each other.

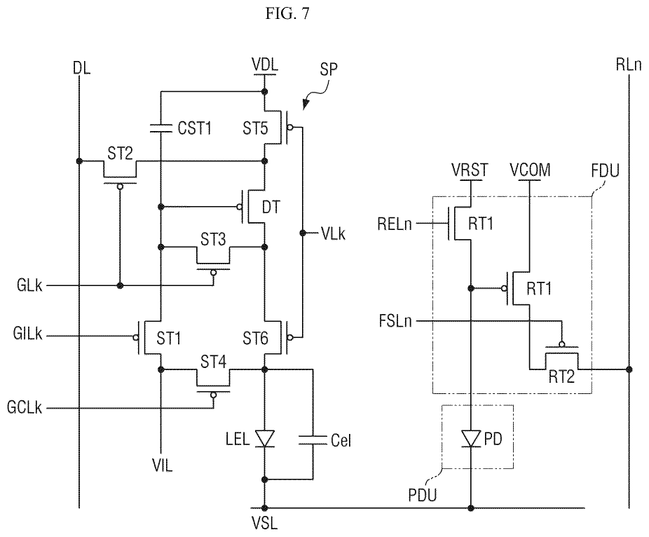

FIG. 7 is a circuit diagram illustrating the display pixel and the light sensing pixel according to an embodiment.

Referring to FIG. 7, each display pixel SP according to an embodiment may be connected to a k-th display initialization line GILk, a k-th display scan line GLk, a k-th display control line GCLk, and a k-th emission control line VLK. The display pixel SP may be connected to a first driving voltage line VDL to which a first driving voltage is supplied, a second driving voltage line VSL to which a second driving voltage is supplied, and a third driving voltage line VIL to which a third driving voltage is supplied. Hereinafter, the alphabets k and n used instead of numbers represent positive integers excluding 0.

The display pixel SP may include the light emitting unit ELU and the pixel driving unit DDU. The light emitting unit ELU may include a light emitting element LEL. The pixel driving unit DDU may include a driving transistor DT, switch elements, and a capacitor CST1. The switch elements include first to sixth transistors ST1, ST2, ST3, ST4, ST5, and ST6. The pixel driving unit DDU may include six transistors, but the present disclosure is not limited thereto. In some embodiments, the pixel driving unit DDU may include a various number of transistors.

The driving transistor DT may include a gate electrode, a first electrode, and a second electrode. The driving transistor DT controls a drain-source current (hereinafter, referred to as a “driving current”) flowing between the first electrode and the second electrode according to a data voltage applied to the gate electrode. The driving current flowing through a channel of the driving transistor DT is proportional to the square of a difference between a voltage Vsg between the first electrode and the gate electrode and a threshold voltage of the driving transistor DT as represented in Equation 1.

$$Ids = {k}^{′} X {( V sg - V th )}^{2} \qquad [ Equation 1 ]$$

Here, Ids represents the driving current, and k′ refers to a proportional coefficient determined by a structure and physical characteristics of the driving transistor, Vsg refers to the voltage between the first electrode and the gate electrode of the driving transistor, and Vth refers to the threshold voltage of the driving transistor.

The light emitting element LEL emits light according to the driving current Ids. The larger the driving current Ids, the larger the amount of light emitted from the light emitting element LEL.

The light emitting element LEL may be an organic light emitting diode including an organic light emitting layer disposed between an anode electrode and a cathode electrode. In some embodiments, the light emitting element LEL may be an inorganic light emitting element including an inorganic semiconductor disposed between an anode electrode and a cathode electrode. In some embodiments, the light emitting element LEL may be a quantum dot light emitting element including a quantum dot light emitting layer disposed between an anode electrode and a cathode electrode. In some embodiments, the light emitting element LEL may be a micro light emitting element including a micro light emitting diode disposed between an anode electrode and a cathode electrode.

The anode electrode of the light emitting element LEL may be connected to a first electrode of the fourth transistor ST4 and a second electrode of the sixth transistor ST6, and the cathode electrode of the light emitting element LEL may be connected to the second driving voltage line VSL. A parasitic capacitance Cel may be formed between the anode electrode and the cathode electrode of the light emitting element LEL.

The first transistor ST1 is turned on by an initialization scan signal of the k-th display initialization line GILk to connect the gate electrode of the driving transistor DT to the third driving voltage line VIL. Accordingly, the third driving voltage VINT of the third driving voltage line VIL may be applied to the gate electrode of the driving transistor DT. A gate electrode of the first transistor ST1 may be connected to the k-th display initialization line GILk, a first electrode of the first transistor ST1 may be connected to the gate electrode of the driving transistor DT, and a second electrode of the first transistor ST1 may be connected to the third driving voltage line VIL.

The second transistor ST2 is turned on by a display scan signal of the k-th display scan line GLk to connect the first electrode of the driving transistor DT to the data line DL. Accordingly, the data voltage of the data line DL may be applied to the first electrode of the driving transistor DT. A gate electrode of the second transistor ST2 may be connected to the k-th display scan line GLk, a first electrode of the second transistor ST2 may be connected to the first electrode of the driving transistor DT, and a second electrode of the second transistor ST2 may be connected to the data line DL.

The third transistor ST3 is turned on by the display scan signal of the k-th display scan line GLk to connect the gate electrode of the driving transistor DT to the second electrode of the driving transistor DT. When the gate electrode and the second electrode of the driving transistor DT are connected to each other, the driving transistor DT serves as a diode. A gate electrode of the third transistor ST3 may be connected to the k-th display scan line GLk, a first electrode of the third transistor ST3 may be connected to the second electrode of the driving transistor DT, and a second electrode of the third transistor ST3 may be connected to the gate electrode of the driving transistor DT.

The fourth transistor ST4 is turned on by a display control signal of the k-th display control line GCLk to connect the anode electrode of the light emitting element LEL to the third driving voltage line VIL. The third driving voltage of the third driving voltage line VIL may be applied to the anode electrode of the light emitting element LEL. A gate electrode of the fourth transistor ST4 may be connected to the k-th display control line GCLk, the first electrode of the fourth transistor ST4 may be connected to the anode electrode of the light emitting element LEL, and a second electrode of the fourth transistor ST4 may be connected to the third driving voltage line VIL.

The fifth transistor ST5 is turned on by an emission signal of the k-th emission control line VLk to connect the first electrode of the driving transistor DT to the first driving voltage line VDL. A gate electrode of the fifth transistor ST5 may be connected to the k-th emission control line VLK, a first electrode of the fifth transistor ST5 may be connected to the first driving voltage line VDL, and a second electrode of the fifth transistor ST5 may be connected to the first electrode of the driving transistor DT.

The sixth transistor ST6 is disposed between the second electrode of the driving transistor DT and the anode electrode of the light emitting element LEL. The sixth transistor ST6 is turned on by an emission control signal of the k-th emission control line VLk to connect the second electrode of the driving transistor DT to the anode electrode of the light emitting element LEL. A gate electrode of the sixth transistor ST6 may be connected to the k-th emission control line VLk, a first electrode of the sixth transistor ST6 may be connected to the second electrode of the driving transistor DT, and the second electrode of the sixth transistor ST6 may be the anode electrode of the light emitting element LEL.

When both the fifth transistor ST5 and the sixth transistor ST6 are turned on, the driving current of the driving transistor DT according to the data voltage applied to the gate electrode of the driving transistor DT may flow to the light emitting element LEL.

The capacitor CST1 is formed between the gate electrode of the driving transistor DT and the first driving voltage line VDL. A first capacitor electrode of the capacitor CST1 may be connected to the gate electrode of the driving transistor DT, and a second capacitor electrode of the capacitor CST1 may be connected to the first driving voltage line VDL.

When the first electrode of each of the first to sixth transistors ST1, ST2, ST3, ST4, ST5, and ST6 and the driving transistor DT is a source electrode, the second electrode of each of the first to sixth transistors ST1, ST2, ST3, ST4, ST5, and ST6 and the driving transistor DT may be a drain electrode. In some embodiments, when the first electrode of each of the first to sixth transistors ST1, ST2, ST3, ST4, ST5, and ST6 and the driving transistor DT is a drain electrode, the second electrode of each of the first to sixth transistors ST1, ST2, ST3, ST4, ST5, and ST6 and the driving transistor DT may be a source electrode.

An active layer of each of the first to sixth transistors ST1, ST2, ST3, ST4, ST5, and ST6 and the driving transistor DT may be formed of one of polysilicon, amorphous silicon, and an oxide semiconductor. In some embodiments, the first to sixth transistors ST1, ST2, ST3, ST4, ST5, and ST6, and the driving transistor DT are formed as P-type metal oxide semiconductor field effect transistors (MOSFETs), but the present disclosure is not limited thereto. For example, the first to sixth transistors ST1, ST2, ST3, ST4, ST5, and ST6, and the driving transistor DT may be formed as N-type MOSFETs. In some embodiments, at least one of the first to sixth transistors ST1, ST2, ST3, ST4, ST5, and ST6 may be formed as an N-type MOSFET and the others may be formed as a P-type MOSFET.

Each of the light sensing pixels LSP is electrically connected to an n-th sensing reset line RELn, an n-th light sensing scan line FSLn, and an n-th light sensing line RLn. Each of the light sensing pixels LSP may be reset by a reset signal from the n-th sensing reset line RELn, and may generate and transmit a light sensing signal to each of the n-th light sensing lines RLn in response to a sensing scan signal from the n-th light sensing scan line FSLn.

Each of the light sensing pixels LSP may include a light sensing unit PDU including a light sensing element PD and a sensing driving unit FDU including first to third sensing transistors RT1 to RT3 and a sensing capacitor (not illustrated). Here, the sensing capacitor may be connected to the light sensing element PD in parallel.

The first sensing transistor RT1 of the sensing driving unit FDU may flow a light sensing current according to a voltage of the light sensing element PD and the sensing capacitor. A current amount of the light sensing current may change depending on a voltage applied to the light sensing element PD and the sensing capacitor. A gate electrode of the first sensing transistor RT1 may be connected to a second electrode of the light sensing element PD. A first electrode of the first sensing transistor RT1 may be connected to a common voltage source VCOM to which a common voltage is applied. A second electrode of the first sensing transistor RT1 may be connected to a first electrode of the second sensing transistor RT2.

The second sensing transistor RT2 may flow the sensing current of the first sensing transistor RT1 to the n-th light sensing line RLn when a sensing scan signal of a gate-on voltage is applied to the n-th light sensing line RLn. The n-th light sensing line RLn may be charged with a sensing voltage by the sensing current. A gate electrode of the second sensing transistor RT2 may be connected to the n-th light sensing scan line FSLn, the first electrode of the second sensing transistor RT2 may be connected to the second electrode of the first sensing transistor RT1, and a second electrode of the second sensing transistor RT2 may be connected to the n-th light sensing line RLn.

The third sensing transistor RT3 may reset the voltage of the light sensing element PD and the sensing capacitor to a reset voltage of a reset voltage source VRST when a reset signal of a gate-on voltage is applied to the n-th sensing reset line RELn. A gate electrode of the third sensing transistor RT3 may be connected to the n-th sensing reset line RELn, a first electrode of the third sensing transistor RT3 may be connected to the reset voltage source VRST, and a second electrode of the third sensing transistor RT3 may be connected to the second electrode of the light sensing element PD.

In some embodiment, the first sensing transistor RT1 and the second sensing transistor RT2 are formed as P-type MOSFETs and the third sensing transistor RT3 is formed as an N-type MOSFET, but an embodiment of the present disclosure is not limited thereto, and the first to third sensing transistors RT1 to RT3 may be selectively formed as the same type MOSFET or different type MOSFETs. One of the first electrode and the second electrode of each of the first sensing transistor RT1, the second sensing transistor RT2, and the third sensing transistor RT3 may be a source electrode and the other of the first electrode and the second electrode of each of the first sensing transistor RT1, the second sensing transistor RT2, and the third sensing transistor RT3 may be a drain electrode.

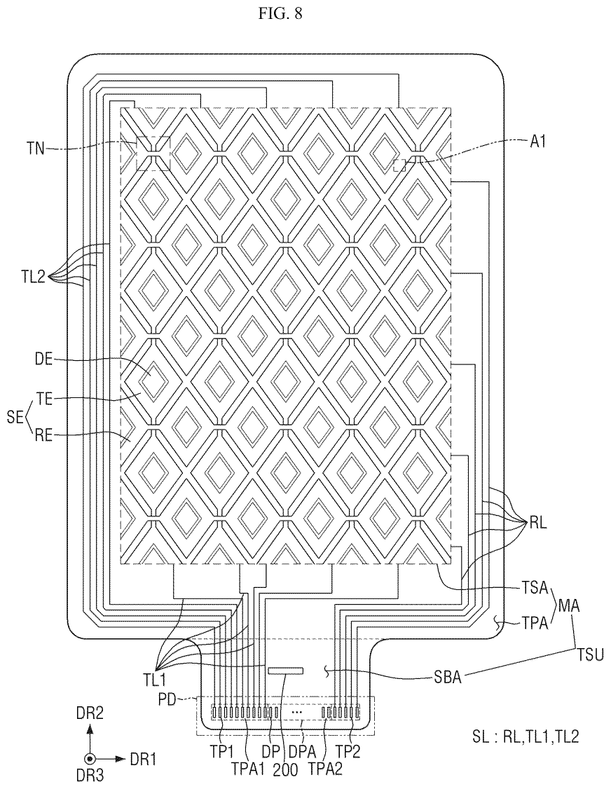

FIG. 8 is a layout diagram illustrating a touch sensing unit illustrated in FIG. 4 according to an embodiment of the present disclosure.

In FIG. 8, touch electrodes SE of a main area MA may sense touch in a mutual capacitive manner. For example, the touch electrodes SE may include two electrodes, for example, driving electrodes TE and sensing electrodes RE and may sense a charge change amount in mutual capacitance of each of a plurality of touch nodes TN through the sensing electrodes RE after applying touch driving signals to the driving electrodes TE, but the present disclosure is not limited thereto.

In FIG. 8, for convenience of explanation, only the driving electrodes TE, the sensing electrodes RE, dummy electrodes DE, touch lines SL, test signal transmitting lines RL, and first and second touch pads TP1 and TP2 have been illustrated.

The main area MA of the touch sensing unit TSU includes a touch sensing area TSA for sensing a user's touch and a touch peripheral area TPA disposed around the touch sensing area TSA. The touch sensing area TSA may overlap the display area DA of FIGS. 1 to 3, and the touch peripheral area TPA may overlap the non-display area NDA of FIGS. 1 to 3.

The driving electrodes TE, the sensing electrodes RE, and the dummy electrodes DE are disposed in the touch sensing area TSA. The driving electrodes TE and the sensing electrodes RE may be electrodes that generate the mutual capacitance to sense touch of an object or a person.

The sensing electrodes RE may be arranged in the first direction DR1 and the second direction DR2. The sensing electrodes RE may be electrically connected with each other in the first direction DR1 in each row. The sensing electrodes RE adjacent to each other in the first direction DR1 may be connected with each other. The sensing electrodes RE adjacent to each other in the second direction DR2 may be electrically disconnected from each other. Accordingly, the touch node TN where mutual capacitance is formed may be disposed at each of intersection parts between the driving electrodes TE and the sensing electrodes RE. The plurality of touch nodes TN may correspond to the intersection parts between the driving electrodes TE and the sensing electrodes RE. For example, overlapping portions of the driving electrodes TE and the sensing electrodes RE may correspond to the touch nodes TN which serve as a capacitance to detect touch by a user's finger, for example.

The driving electrodes TE may be arranged in the first direction DR1 and the second direction DR2. The driving electrodes TE adjacent to each other in the first direction DR1 may be electrically disconnected from each other. The driving electrodes TE may be electrically connected to each other in the second direction DR2 in each column. The driving electrodes TE adjacent to each other in the second direction DR2 may be connected with each other through a separate connection electrode.

Each of the dummy electrodes DE may be surrounded by the driving electrode TE or the sensing electrode RE. Each of the dummy electrodes DE may be electrically disconnected from the driving electrode TE or the sensing electrode RE. Each of the dummy electrodes DE may be spaced apart from the driving electrode TE or the sensing electrode RE. Each of the dummy electrodes DE may be electrically floated. In some embodiments, each of the driving electrodes TE, the sensing electrodes RE, and the dummy electrodes DE has a rhombic shape when viewed in a plan view, but the present disclosure is not limited thereto. For example, each of the driving electrodes TE, the sensing electrodes RE, and the dummy electrodes DE may have a rectangular shape other than the rhombic shape, polygonal shapes other than the rectangular shape or the rhombic shape, a circular shape, or an elliptical shape when viewed in a plan view.

The touch lines SL may be disposed in the touch peripheral area TPA. The touch lines SL may include first touch driving lines TL1 and second touch driving lines TL2 connected to the driving electrodes TE and touch sensing lines RL connected to the sensing electrodes RE.

The respective sensing electrodes RE disposed at one end of the touch sensing area TSA may be connected to the touch sensing lines RL in a one-to-one manner. For example, as illustrated in FIG. 8, the respective sensing electrodes RE disposed at a right end among the sensing electrodes RE electrically connected to each other in the first direction DR1 may be connected to the respective touch sensing lines RL. The respective touch sensing lines RL may be connected to the second touch pads TP2 disposed in a pad part FD in one-to-one manner.

The driving electrodes TE disposed at one end of the touch sensing area TSA may be connected to the first touch driving lines TL1 in a one-to-one manner, and the driving electrodes TE disposed at the other end of the touch sensing area TSA may be connected to the second touch driving lines TL2 in a one-to-one manner. For example, the driving electrodes TE disposed at a lower end among the driving electrodes TE electrically connected to each other in the second direction DR2 may be connected to the first touch driving lines TL1, respectively, and the driving electrodes TE disposed at an upper end among the driving electrodes TE electrically connected to each other in the second direction DR2 may be connected to the second touch driving lines TL2, respectively. The second touch driving lines TL2 may be connected to the driving electrodes TE on the upper side of the touch sensing area TSA via the outer left side of the touch sensing area TSA.

The first touch driving lines TL1 and the second touch driving lines TL2 may be connected to first touch pads TP1 disposed in the pad part PD in a one-to-one manner. The driving electrodes TE are connected to the first and second touch driving lines TL1 and TL2 on opposite sides of the touch sensing area TSA to receive touch driving signals. Accordingly, it is possible to prevent a difference between the touch driving signals applied to the driving electrodes TE disposed on the lower side of the touch sensing area TSA and the touch driving signals applied to the driving electrodes TE disposed on the upper side of the touch sensing area TSA from occurring due to an RC delay of the touch driving signals.

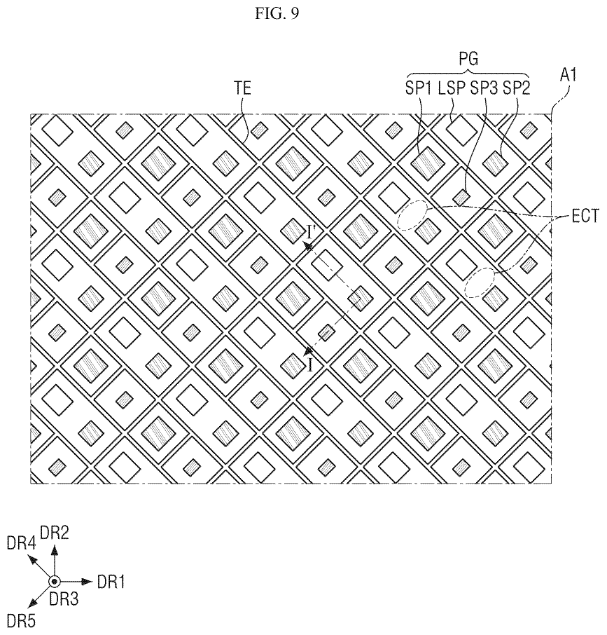

FIG. 9 is an enlarged view of area A1 of FIG. 8 according to an embodiment of the present disclosure.

Referring to FIG. 9, each pixel group PG (i.e., each unit pixel group) constituting each unit pixel USP includes first to third display pixels SP1, SP2, and SP3 and a light sensing pixel LSP.

The first to third display pixels SP1, SP2, and SP3 may include first to third emission areas, respectively. For example, the first emission area of the first display pixel SP1 may emit light of a first color or red light, and the second emission area of the second display pixel SP2 may emit light of a second color or green light, and the third emission area of the third display pixel SP3 may emit light of a third color or blue light. Each pixel group PG may express a white gradation through the first to third emission areas EA1 to EA3.

The light sensing pixels LSP may sense light incident from the front surface to the light sensing area, that is, light reflected from a finger in close contact with the front surface.

The first to third display pixels SP1, SP2, and SP3 and light sensing pixels LSP constituting each pixel group PG may be arranged in a Pentile™ matrix structure. Accordingly, the first to third emission areas of the first to third display pixels SP1, SP2, and SP3 and the light sensing area of the light sensing pixel LSP may be arranged in a Pentile™ matrix structure. For example, the first and third display pixels SP1 and SP3 may be alternately disposed in the fourth direction DR4, and the second display pixel SP2 and the light sensing pixel LSP may be alternately disposed in the fourth direction DR4. The first display pixel SP1 and the light sensing pixel LSP may be alternately disposed in the fifth direction DR5, and the second display pixel SP2 and third display pixel SP3 may be alternately disposed in the fifth direction DR5.

During the fingerprint sensing period, the main driving circuit 200 may be driven so that at least one display pixel among the first to third display pixels SP1, SP2, and SP3 emits light, and the reflected light of the front surface by the light sensing pixels LSP may be sensed. For example, during the fingerprint sensing period, the main driving circuit 200 may drive the display scan driver 110 and supply the green data voltage to the second display pixels SP2. The light sensing scan driver 120 is driven so that the reflected light of the front surface is sensed by the light sensing pixels LSP. Accordingly, each of the light sensing pixels LSP may generate a light sensing signal corresponding to the amount of reflected light incident from the front direction and output the light sensing signal to the light sensing line ERL. In some embodiments, during the fingerprint sensing period, the main driving circuit 200 may drive the display scan driver 110 and supply data voltages to the first or third display pixels SP1 or SP3 so that reflected light of the front surface is sensed by the light sensing pixels LSP. The main driving circuit 200 converts light sensing signals input through the light sensing lines ERL into digital signals and compares and analyzes the converted digital signals with reference data signals to confirm fingerprint information.

Referring to FIG. 9 together with FIG. 8, the plurality of driving electrodes TE, the plurality of sensing electrodes RE, and the plurality of dummy electrodes DE may be formed in a mesh structure or a net structure when viewed in a plan view, corresponding to the layout structure of the first to third display pixels SP1, SP2, and SP3 and the light sensing pixel LSP arranged in a Pentile™ matrix structure.

In some embodiments, the plurality of driving electrodes TE, the plurality of sensing electrodes RE, and the plurality of dummy electrodes DE may surround the first to third display pixels SP1, SP2, and SP3 of each pixel group PG and the light-sensing area of the light sensing pixels LSP to form a mesh structure or a net structure when viewed in a plan view.

The plurality of driving electrodes TE, the plurality of sensing electrodes RE, and the plurality of dummy electrodes DE may not overlap the first to third emission areas and the light sensing area. Accordingly, the display device 10 may prevent the luminance of light emitted from the first to third emission areas from being reduced by the touch sensing unit TSU.

Referring to FIG. 9, at least one of the plurality of driving electrodes TE, the plurality of sensing electrodes RE, and the plurality of dummy electrodes DE includes open areas ECT in which no electrode is formed between light sensing pixels LSP and at least one display pixel SP1, SP2, and SP3 adjacent to the light sensing pixels LSP. For example, at least one electrode of the plurality of driving electrodes TE, the plurality of sensing electrodes RE, and the plurality of dummy electrodes DE defines open areas ECT in which no touch electrode is formed between light sensing pixels LSP and at least one display pixel SP1, SP2, and SP3 adjacent to the light sensing pixels LSP in each unit pixel.

For a more specific example, at least one of the plurality of driving electrodes TE, the plurality of sensing electrodes RE, and the plurality of dummy electrodes DE includes open areas ECT in which no electrode is formed between at least one emission area of the emission areas of the first to third display pixels SP1, SP2, and SP3 and the light sensing area of the light sensing pixel LSP. Here, the open area ECT of each of the plurality of driving electrodes TE, the plurality of sensing electrodes RE, and the plurality of dummy electrodes DE may be an area in which the plurality of driving electrodes TE, the plurality of sensing electrodes RE, and the plurality of dummy electrodes DE are partially short-circuited or cut.

For example, at least one of the plurality of driving electrodes TE, the plurality of sensing electrodes RE, and the plurality of dummy electrodes DE may be formed in a mesh structure when viewed in a plan view, and may include open areas ECT in which no electrode is formed between the emission area of the second display pixel SP2 and the light sensing area of the light sensing pixels LSP. For example, the open areas ECT in which no electrode is formed may be included in areas between the second display pixel SP2 and the light sensing pixel LSP. On the other hand, the open areas ECT in which no electrode is formed may be included between the emission area of the second display pixels SP2 and the light sensing area of the light sensing pixels LSP, respectively.

When the open areas ECT are disposed between the emission area of the second display pixels SP2 and the light sensing area of the light sensing pixels LSP, the main driving circuit 200 may drive the second display pixels SP2 to emit green light and sense the reflected light of the front surface by the light sensing pixels LSP during the fingerprint sensing period. Each light sensing pixel LSP may generate a light sensing signal corresponding to the amount of green light reflected from the front direction.

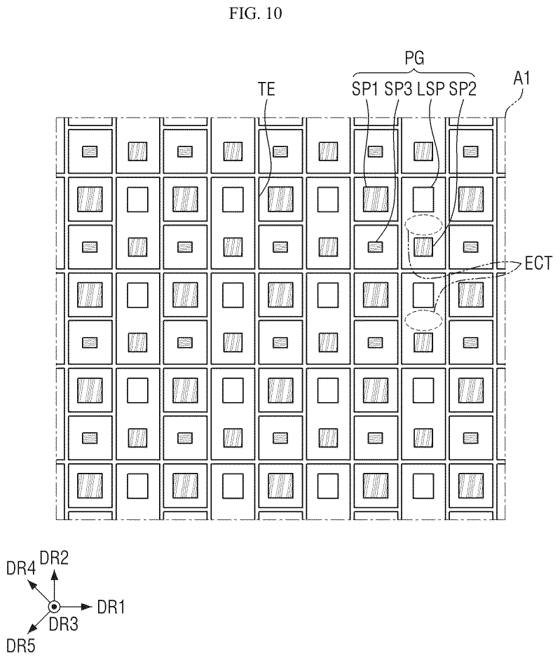

FIG. 10 is an enlarged view illustrating area A1 of FIG. 8 according to an embodiment of the present disclosure.

Referring to FIG. 10, the first to third display pixels SP1, SP2, and SP3 and light sensing pixels LSP constituting each pixel group PG may be arranged in a vertical and horizontal stripe structure. Accordingly, the first to third emission areas of the first to third display pixels SP1, SP2, and SP3 and the light sensing area of the light sensing pixel LSP may be arranged in a vertical and horizontal stripe structure. For example, the first display pixel SP1 and the light sensing pixel LSP may be alternately disposed in the first direction DR1, and the second display pixel SP2 and third display pixel SP3 may be alternately disposed in the first direction DR1. The first display pixel SP1 and the third display pixel SP3 may be alternately disposed in the second direction DR2, and the light sensing pixel LSP and second display pixel SP2 may be alternately disposed in the second direction DR2.

Referring to FIG. 10, the plurality of driving electrodes TE, the plurality of sensing electrodes RE, and the plurality of dummy electrodes DE may be formed in a mesh structure or a net structure when viewed in a plan view, corresponding to the layout structure of the first to third display pixels SP1, SP2, and SP3 and the light sensing pixel LSP arranged in a vertical and horizontal stripe structure.

In some embodiments, the plurality of driving electrodes TE, the plurality of sensing electrodes RE, and the plurality of dummy electrodes DE may be formed in a mesh structure surrounding the first to third emission areas of the first to third display pixels SP1, SP2, and SP3, and the light sensing area of the light sensing pixels LSP.

At least one of the plurality of driving electrodes TE, the plurality of sensing electrodes RE, and the plurality of dummy electrodes DE includes open areas ECT in which no electrode is formed between at least one emission area among the emission areas of the first to third display pixels SP1, SP2, and SP3 and the light sensing area of the light sensing pixel LSP.

For example, at least one of the plurality of driving electrodes TE, the plurality of sensing electrodes RE, and the plurality of dummy electrodes DE may be formed in a mesh structure when viewed in a plan view, and may include opening areas ECT in which no electrode is formed between the emission area of the second display pixel SP2 and the light sensing area of the light sensing pixels LSP. For example, the open areas ECT in which no electrode is formed may be included in areas between the second display pixel SP2 and the light sensing pixel LSP. On the other hand, the open areas ECT in which no electrode is formed may be included between the emission area of the second display pixels SP2 and the light sensing area of the light sensing pixels LSP, respectively.

When the open areas ECT are disposed between the emission area of the second display pixels SP2 and the light sensing area of the light sensing pixels LSP, the main driving circuit 200 may drive the second display pixels SP2 to emit green light and sense the reflected light of the front surface by the light sensing pixels LSP during the fingerprint sensing period. Each light sensing pixel LSP may generate a light sensing signal corresponding to the amount of green light reflected from the front direction.

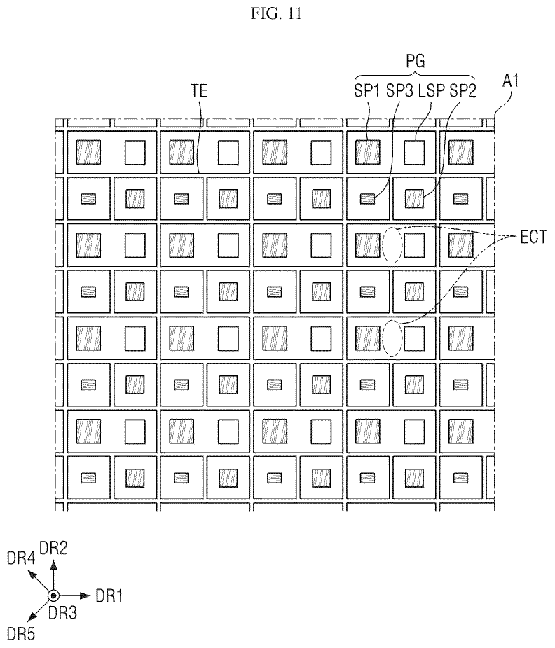

FIG. 11 is an enlarged view of area A1 of FIG. 8 according to an embodiment of the present disclosure.

Referring to FIG. 11, the first to third emission areas of the first to third display pixels SP1, SP2, and SP3 and the light sensing area of the light sensing pixel LSP may be arranged in a vertical and horizontal stripe structure. For example, the first display pixel SP1 and the light sensing pixel LSP may be alternately disposed in the first direction DR1, and the second display pixel SP2 and third display pixel SP3 may be alternately disposed in the first direction DR1. The first display pixel SP1 and the third display pixel SP3 may be alternately disposed in the second direction DR2, and the light sensing pixel LSP and second display pixel SP2 may be alternately disposed in the second direction DR2.

Referring to FIG. 11, the plurality of driving electrodes TE, the plurality of sensing electrodes RE, and the plurality of dummy electrodes DE may be formed in a mesh structure or a net structure when viewed in a plan view, corresponding to the layout structure of the first to third display pixels SP1, SP2, and SP3 and the light sensing pixel LSP arranged in a vertical and horizontal stripe structure.

In some embodiments, the plurality of driving electrodes TE, the plurality of sensing electrodes RE, and the plurality of dummy electrodes DE may be formed in a mesh structure surrounding the first to third emission areas of the first to third display pixels SP1, SP2, and SP3, and the light sensing area of the light sensing pixels LSP.

At least one of the plurality of driving electrodes TE, the plurality of sensing electrodes RE, and the plurality of dummy electrodes DE includes open areas ECT in which no electrode is formed between at least one emission area among the emission areas of the first to third display pixels SP1, SP2, and SP3 and the light sensing area of the light sensing pixel LSP.

For example, at least one of the plurality of driving electrodes TE, the plurality of sensing electrodes RE, and the plurality of dummy electrodes DE may be formed in a mesh structure when viewed in a plan view, and may include open areas ECT in which no electrode is formed between the emission area of the first display pixel SP1 and the light sensing area of the light sensing pixels LSP. For example, the open areas ECT in which no electrode is formed may be included in areas between the first display pixel SP1 and the light sensing pixel LSP. On the other hand, the open areas ECT in which no electrode is formed may be included between the emission area of the first display pixel SP1 and the light sensing area of the light sensing pixels LSP, respectively.

When the open areas ECT are disposed between the emission area of the first display pixels SP1 and the light sensing area of the light sensing pixels LSP, the main driving circuit 200 may drive the first display pixels SP1 to emit red light and sense the reflected light of the front surface by the light sensing pixels LSP during the fingerprint sensing period. Each light sensing pixel LSP may generate a light sensing signal corresponding to the amount of red light reflected from the front direction. The main driving circuit 200 converts light sensing signals input through the light sensing lines ERL into digital signals and compares and analyzes the converted digital signals with reference data signals to confirm fingerprint information.

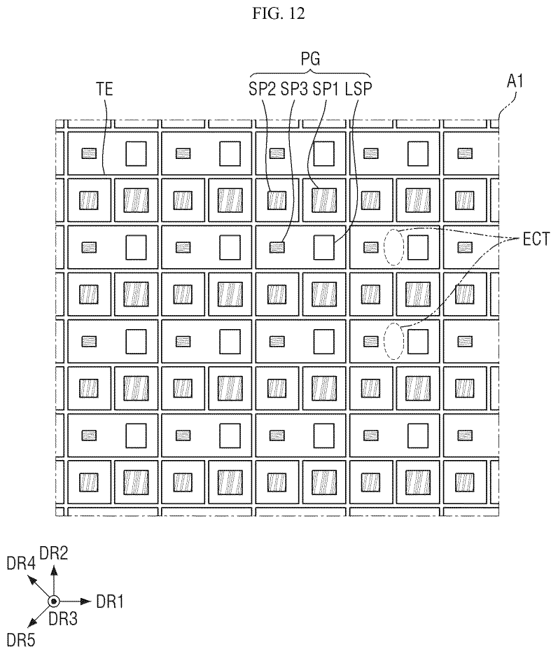

FIG. 12 is an enlarged view of area A1 of FIG. 8 according to an embodiment of the present disclosure.

Referring to FIG. 12, the first to third emission areas of the first to third display pixels SP1, SP2, and SP3 and the light sensing area of the light sensing pixel LSP may be arranged in a vertical and horizontal stripe structure.

For example, the first display pixel SP1 and the second display pixel SP2 may be alternately disposed in the first direction DR1, and the third display pixel SP3 and light sensing pixel LSP may be alternately disposed in the first direction DR1. The and the second display pixel SP2 and the third display pixel SP3 may be alternately disposed in the second direction DR2, and the first display pixel SP1 and the light sensing pixel LSP may be alternately disposed in the second direction DR2.

Referring to FIG. 12, the plurality of driving electrodes TE, the plurality of sensing electrodes RE, and the plurality of dummy electrodes DE may be formed in a mesh structure or a net structure when viewed in a plan view, corresponding to the layout structure of the first to third display pixels SP1, SP2, and SP3 and the light sensing pixel LSP arranged in a vertical and horizontal stripe structure.

In some embodiments, the plurality of driving electrodes TE, the plurality of sensing electrodes RE, and the plurality of dummy electrodes DE may be formed in a mesh structure surrounding the first to third emission areas of the first to third display pixels SP1, SP2, and SP3, and the light sensing area of the light sensing pixels LSP.

At least one of the plurality of driving electrodes TE, the plurality of sensing electrodes RE, and the plurality of dummy electrodes DE includes open areas ECT in which no electrode is formed between at least one emission area among the emission areas of the first to third display pixels SP1, SP2, and SP3 and the light sensing area of the light sensing pixel LSP.

For example, at least one of the plurality of driving electrodes TE, the plurality of sensing electrodes RE, and the plurality of dummy electrodes DE may be formed in a mesh structure when viewed in a plan view, and may include open areas ECT in which no electrode is formed between the emission area of the third display pixel SP3 and the light sensing area of the light sensing pixels LSP. For example, the open areas ECT in which no electrode is formed may be included in areas between the third display pixel SP3 and the light sensing pixel LSP. On the other hand, the open areas ECT in which no electrode is formed may be included between the emission area of the third display pixel SP3 and the light sensing area of the light sensing pixels LSP, respectively.

When the open areas ECT are disposed between the emission area of the third display pixels SP3 and the light sensing area of the light sensing pixels LSP, the main driving circuit 200 may drive the third display pixels SP3 to emit blue light and sense the reflected light of the front surface by the light sensing pixels LSP during the fingerprint sensing period. Each light sensing pixel LSP may generate a light sensing signal corresponding to the amount of blue light reflected from the front direction. The main driving circuit 200 converts light sensing signals input through the light sensing lines ERL into digital signals and compares and analyzes the converted digital signals with reference data signals to confirm fingerprint information.

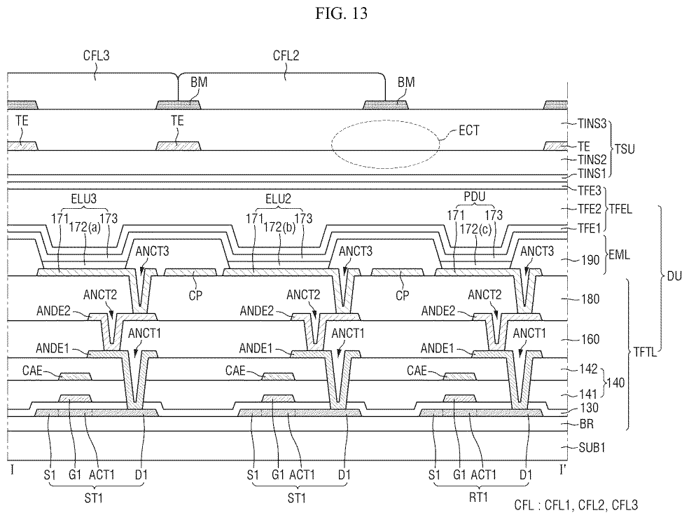

FIG. 13 is a cross-sectional view of a cross section I-I′ of FIG. 9 according to an embodiment of the present disclosure.

FIG. 13 is a cross-sectional view showing a portion of the cross-sections of the third light emitting unit ELU3 and the third pixel driving unit DDU3, the cross-sections of the second light emitting unit ELU2 and the second pixel driving unit DDU2, and the cross-sections of the light sensing unit PDU and the sensing driving unit FDU.

Referring to FIG. 13, a barrier layer BR may be disposed on a substrate SUB. The substrate SUB may include or may be formed of an insulating material such as a polymer resin. For example, the substrate SUB may include or may be formed of polyimide. The substrate SUB may be a flexible substrate that may be bent, folded, and rolled.

The barrier layer BR is a layer for protecting transistors of a thin film transistor layer TFTL and light emitting layers 172 of a light emitting element layer EML from moisture permeating through the substrate SUB vulnerable to moisture permeation. The barrier layer BR may include a plurality of inorganic layers that are alternately stacked. For example, the barrier layer BR may be formed as multiple layers in which one or more inorganic layers of a silicon nitride layer, a silicon oxynitride layer, a silicon oxide layer, a titanium oxide layer, and an aluminum oxide layer are alternately stacked.

The transistor ST1 of each pixel driving unit and a sensing transistor RT1 of the sensing driving units FDU may be disposed on the barrier layer BR. Each transistor ST1 and each sensing transistor RT1 include an active layer ACT1, a gate electrode G1, a source electrode S1, and a drain electrode D1.

In some embodiments, the active layer ACT1, the source electrode S1, and the drain electrode D1 of the thin film transistors ST1 may be disposed on the barrier layer BR. The active layer ACT1 of the thin film transistor ST1 may include or may be formed of polycrystalline silicon, single crystal silicon, low-temperature polycrystalline silicon, amorphous silicon, or an oxide semiconductor. The active layer ACT1 overlapping the gate electrode G1 in the third direction DR3, which is a thickness direction of the substrate SUB, may be defined as a channel region. For example, the third direction DR3 may be perpendicular to an upper surface of the substrate SUB. The source electrode S1 and the drain electrode D1 are regions that do not overlap the gate electrode G1 in the third direction DR3, and may have conductivity by doping a silicon semiconductor or an oxide semiconductor with ions or impurities.

A gate insulating layer 130 may be disposed on the active layer ACT1, the source electrode S1, and the drain electrode D1 of the thin film transistors ST1 and the sensing driving units FDU. The gate insulating layer 130 may be formed as an inorganic layer such as a silicon nitride layer, a silicon oxynitride layer, a silicon oxide layer, a titanium oxide layer, or an aluminum oxide layer.

The gate electrode G1 of the thin film transistor ST1 may be disposed on the gate insulating layer 130. The gate electrode G1 may overlap the active layer ACT1 in the third direction DR3. The gate electrode G1 may be formed as a single layer or multiple layers made of one of molybdenum (Mo), aluminum (Al), chromium (Cr), gold (Au), titanium (Ti), nickel (Ni), neodymium (Nd), and copper (Cu), or an alloy thereof.

A first interlayer insulating layer 141 may be disposed on the gate electrodes G1 of the first thin film transistors ST1 and the sensing driving units FDU. The first interlayer insulating layer 141 may be formed as an inorganic layer such as a silicon nitride layer, a silicon oxynitride layer, a silicon oxide layer, a titanium oxide layer, and an aluminum oxide layer. The first interlayer insulating layer 141 may be formed as a plurality of inorganic layers.

Capacitor electrodes CAE may be disposed on the first interlayer insulating layer 141. The capacitor electrode CAE may overlap the gate electrode G1 of the first thin film transistor ST1 in the third direction DR3. Since the first interlayer insulating layer 141 has a predetermined dielectric constant, the capacitor electrode CAE, the gate electrode G1, and the first interlayer insulating layer 141 disposed between the capacitor electrode CAE and the gate electrode G1 may form a capacitor. The capacitor electrode CAE may be formed as a single layer or multiple layers made of one of molybdenum (Mo), aluminum (Al), chromium (Cr), gold (Au), titanium (Ti), nickel (Ni), neodymium (Nd), and copper (Cu), and an alloy thereof.

A second interlayer insulating layer 142 may be disposed on the capacitor electrode CAE. The second interlayer insulating layer 142 may be formed as an inorganic layer such as a silicon nitride layer, a silicon oxynitride layer, a silicon oxide layer, a titanium oxide layer, and an aluminum oxide layer. The second interlayer insulating layer 142 may be formed as a plurality of inorganic layers.

First anode connection electrodes ANDE1 may be disposed on the second interlayer insulating layer 142. The first anode connection electrode ANDE1 may be connected to the drain electrode D1 of the thin film transistor ST1 through a first connection contact hole ANCT1 penetrating through the gate insulating layer 130, the first interlayer insulating layer 141, and the second interlayer insulating layer 142. The first anode connection electrode ANDE1 may be formed as a single layer or multiple layers made of one of molybdenum (Mo), aluminum (Al), chromium (Cr), gold (Au), titanium (Ti), nickel (Ni), neodymium (Nd), and copper (Cu), and an alloy thereof.

A first planarization layer 160 for planarizing a step due to the thin film transistor ST1 may be disposed on the first anode connection electrode ANDE1. The first planarization layer 160 may be formed as an organic layer made of an acrylic resin, an epoxy resin, a phenolic resin, a polyamide resin, a polyimide resin, or the like. For example, the first planarization layer 160 may be formed on the first anode connection electrode ANDE1 to provide a polarized upper surface for a subsequent process.

Second anode connection electrodes ANDE2 may be disposed on the first planarization layer 160. The second anode connection electrode ANDE2 may be connected to the first anode connection electrode ANDE1 through a second connection contact hole ANCT2 penetrating through the first planarization layer 160. The second anode connection electrode ANDE2 may be formed as a single layer or multiple layers made of one of molybdenum (Mo), aluminum (Al), chromium (Cr), gold (Au), titanium (Ti), nickel (Ni), neodymium (Nd), and copper (Cu), and an alloy thereof.

A second planarization layer 180 may be disposed on the second anode connection electrodes ANDE2. The second planarization layer 180 may be formed as an organic layer made of an acrylic resin, an epoxy resin, a phenolic resin, a polyamide resin, a polyimide resin, or the like. For example, the second planarization layer 180 may be formed on the second anode connection electrode ANDE2 to provide a polarized upper surface for a subsequent process.

The first electrodes (or pixel electrodes) of the light emitting units ELU1 to ELU3 and the first electrodes (or pixel electrodes) of the light sensing unit PDU may be disposed on the second planarization layer 180. Each of the first to third light emitting units ELU1 to ELU3 includes a first electrode 171, an organic light emitting layer 172(b), and a common electrode 173. The present invention is not limited thereto. A fourth light emitting unit may be disposed on the second planarization layer 180 with the first to third light emitting units ELU1 to ELU3. In some embodiments, the fourth light emitting unit may be formed together when the first to third light emitting units ELU1 to ELU3, and the fourth light emitting unit may include a first electrode 171, an infrared light emitting layer 172(a), and a common electrode 173. The light sensing unit PDU includes a first electrode 171, an infrared sensing layer 172(c), and a common electrode 173.

The first electrodes 171 may be connected to the second anode connection electrode ANDE2 through a third connection contact hole ANCT3 penetrating the second planarization layer 180. The first electrodes 171 may be formed of a conductive material having a high reflectance, such as a stacked structure (Ti/Al/Ti) of aluminum and titanium, a stacked structure (ITO/Al/ITO) of aluminum and indium tin oxide (ITO), an APC alloy, or a stacked structure (ITO/APC/ITO) of an APC alloy and ITO. The APC alloy is an alloy of silver (Ag), palladium (Pd) and copper (Cu).

A pixel defining layer 190 may be formed on the second planarization layer 180 to cover all the first electrodes 171.

The pixel defining layer 190 may be formed on the second planarization layer 180 to partition the first electrodes 171 and may thus define each of the light sensing unit PDU and the first to third light emitting units ELU1 to ELU3. The pixel defining layer 190 may cover the edge of the first electrode 171. The pixel defining layer 190 may be formed as a transparent organic layer to minimize its influence on the infrared (IR) reflectivity. The pixel defining layer 190 may be formed as an organic layer such as a photosensitive polyimide resin layer, a polyamide resin layer, a black pixel defining layer (PDL), or a polyimide resin layer.

An organic light emitting layer 172(b) may be formed on the first electrode 171 of the first to third light emitting units ELU1 to ELU3. The organic light emitting layer 172(b) may include an organic material and may emit light of a predetermined color. For example, the organic light emitting layer 172(b) includes a hole transporting layer, an organic material layer, and an electron transporting layer.

In some embodiments, an infrared light emitting layer 172(a) may be formed on the first electrode 171 of the fourth light emitting unit. The infrared light emitting layer 172(a) may include at least one organic material selected from a low molecular weight boron-dipyrromethene derivative (BODIPY-Ph), acetone including a low molecular weight boron-dipyrromethene derivative (BODIPY-Ph), hydrocarbon (e.g., rubrene), N,N′-Di(naphthalen-1-yl)-N,N′-diphenyl-benzidine (NPB), and tris-8-hydroxyquinoline aluminum (Alq3).

The infrared sensing layer 172(c) of each light sensing unit PDU is a PIN semiconductor layer. The PIN semiconductor layer may include a P-type semiconductor layer connected to the first electrode 171, an N-type semiconductor layer connected to the common electrode 173, and an I-type semiconductor layer disposed between the P-type semiconductor layer and the N-type semiconductor layer. The I-type semiconductor layer may be depleted by the P-type semiconductor layer and the N-type semiconductor layer, and holes and electrons generated by reflected light may be drifted by the electric field. Accordingly, the holes may be collected to the anode electrode through the P-type semiconductor layer, and the electrons may be collected to the cathode electrode through the N-type semiconductor layer.

The common electrode 173 may be formed of a transparent conductive material (TCO) such as ITO and indium zinc oxide (IZO) through which light transmits or a semi-transmissive conductive material such as magnesium (Mg), silver (Ag), and an alloy of magnesium (Mg) and silver (Ag). When the common electrode 173 is formed of the semi-transmissive conductive material, emission efficiency may be increased using a micro cavity formed in the common electrode 173.

An encapsulation layer TFEL may be disposed on the common electrode 173. The encapsulation layer TFEL includes at least one inorganic layer in order to prevent oxygen or moisture from permeating into the first to third light emitting units ELU1 to ELU3 and the light sensing units PDU. The encapsulation layer TFEL includes at least one organic layer in order to protect the light emitting element layer EML from foreign materials such as dust. For example, the encapsulation layer TFEL includes a first encapsulation inorganic layer TFE1, an encapsulation organic layer TFE2, and a second encapsulation inorganic layer TFE3.

The first encapsulation inorganic layer TFE1 may be disposed on the common electrode 173. The encapsulation organic layer TFE2 may be disposed on the first encapsulation inorganic layer TFE1. The second encapsulation inorganic layer TFE3 may be disposed on the encapsulation organic layer TFE2. The first encapsulation inorganic layer TFE1 and the second encapsulation inorganic layer TFE3 may be formed as multiple layers in which one or more inorganic layers of a silicon nitride layer, a silicon oxynitride layer, a silicon oxide layer, a titanium oxide layer, or an aluminum oxide layer are alternately stacked. The encapsulation organic layer TFE2 may be an organic layer made of an acrylic resin, an epoxy resin, a phenolic resin, a polyamide resin, a polyimide resin, or the like.

A touch sensing unit TSU may be disposed on the encapsulation layer TFEL. As described above, the touch sensing unit TSU includes a first touch insulating layer TINS1, connection electrodes, a second touch insulating layer TINS2, driving electrodes TE, dummy electrodes DE, and sensing electrodes RE.

The first touch insulating layer TINS1 is formed on the front surfaces of the touch sensing area TSA and the touch peripheral area TPA. The first touch insulating layer TINS1 may be formed as an inorganic layer such as a silicon nitride layer, a silicon oxynitride layer, a silicon oxide layer, a titanium oxide layer, and an aluminum oxide layer.

The connection electrode may be formed on the first touch insulating layer TINS1 of the touch sensing area TSA. A second touch insulating layer TINS2 is formed on the front surface of the first touch insulating layer TINS1. The second touch insulating layer TINS2 may be formed as an inorganic layer such as a silicon nitride layer, a silicon oxynitride layer, a silicon oxide layer, a titanium oxide layer, and an aluminum oxide layer. In some embodiments, second touch insulating layer TINS2 may be formed as an organic layer made of an acrylic resin, an epoxy resin, a phenolic resin, a polyamide resin, a polyimide resin, or the like.

Driving electrodes TE, sensing electrodes RE, and dummy electrodes DE may be formed and disposed on the second touch insulating layer TINS2 of the touch sensing area TSA. Driving electrodes TE, sensing electrodes RE, and dummy electrodes DE may be formed of one of molybdenum (Mo), aluminum (Al), chromium (Cr), gold (Au), titanium (Ti), nickel (Ni), neodymium (Nd) and copper (Cu) and an alloy thereof.

When the driving electrodes TE, the sensing electrodes RE, and the dummy electrodes DE are formed, the first and second touch driving lines TL1 and TL2 as shown in FIG. 8 may be formed and disposed in the touch peripheral area TPA through the same patterning process and the same metal material as the driving electrodes TE, the sensing electrodes RE, and the dummy electrodes DE. Here, the driving electrodes TE, the sensing electrodes RE, and the dummy electrodes DE are formed in a mesh structure when viewed in a plan view. At least one of the driving electrodes TE, the sensing electrodes RE, and the dummy electrodes DE may include open areas ECT in which electrodes are not formed between light sensing pixels LSP and at least one display pixel SP1, SP2, and SP3 adjacent to the light sensing pixels LSP. For example, the driving electrodes TE may include open areas ECT in which no electrode is formed between the emission area of the second display pixel SP2 and the light sensing area of the light sensing pixel LSP.

Since no electrode is formed between the emission area of the second display pixel SP2 and the light sensing area of the light sensing pixel LSP, the light emitted from the emission area of the second display pixel SP2 is not reflected by the electrode between the light sensing areas and is emitted to the front. That is, noise due to reflected light may be minimized.

A third touch insulating layer TINS3 is formed on the second touch insulating layer TINS2 including the driving electrodes TE, the sensing electrodes RE, and the dummy electrodes DE. A black matrix BM may be formed on the third touch insulating layer TINS3 to divide the light sensing units PDU and block light.

A color filter layer CFL may be formed on the third touch insulating layer TINS3 including the black matrix BM. The color filter layer CFL includes a plurality of first to third color filters CFL1, CFL2, and CFL3. For example, the color filter layer CFL may be formed on the third touch insulating layer TINS3 to overlap each of the first to third emission areas. For example, the second color filter CFL2 may be disposed in the second emission area emitting second color light, and the third color filter CFL3 may be disposed in the third emission area emitting third color light.

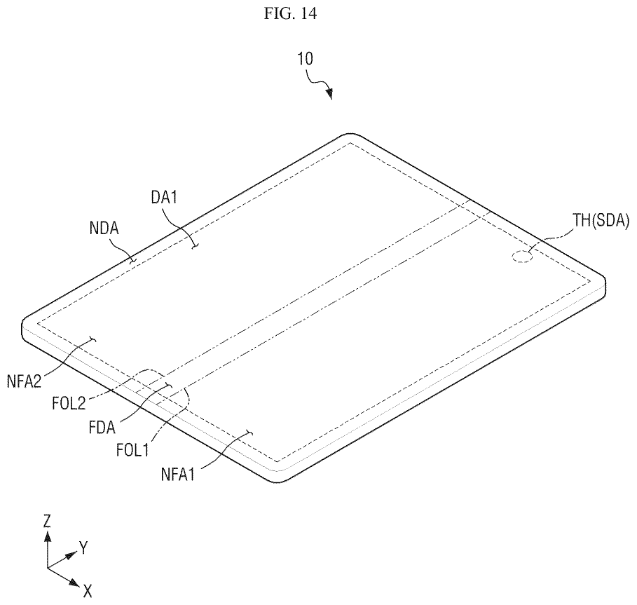

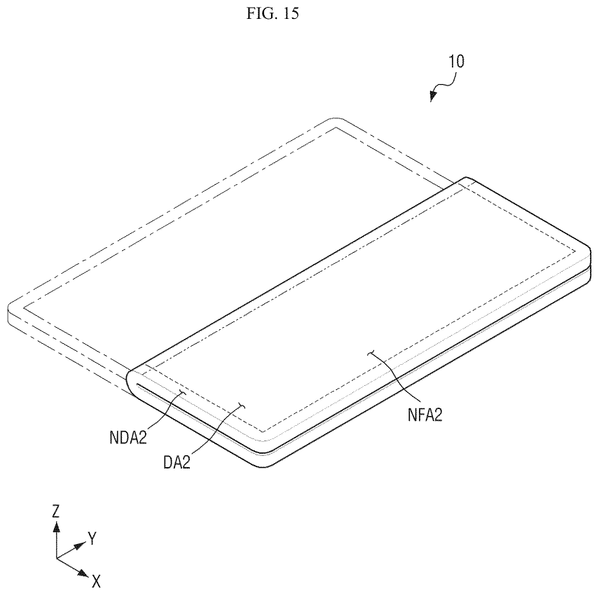

FIGS. 14 and 15 are perspective views illustrating a display device according to an embodiment of the present disclosure.

In FIGS. 14 and 15, a display device 10 is a foldable display device folded in a first direction (X-axis direction). The display device 10 may be maintained in both a folded state and an unfolded state. The display device 10 may be folded in an in-folding manner in which a front surface thereof is disposed inside. When the display device 10 is bent or folded in the in-folding manner, front surfaces of the display device 10 may face each other. In some embodiments, the display device 10 may be folded in an out-folding manner in which a front surface thereof is disposed outside. When the display device 10 is bent or folded in the out-folding manner, rear surfaces of the display device 10 may face each other.

A first non-folding area NFA1 may be disposed on one side, for example, the right side of a folding area FDA. A second non-folding area NFA2 may be disposed on the other side, for example, on the left side of the folding area FDA. The touch sensing units TSU according to an embodiment of the present disclosure may be formed and disposed on the first non-folding area NFA1 and the second non-folding area NFA2, respectively.

A first folding line FOL1 and a second folding line FOL2 may extend in a second direction (Y-axis direction), and the display device 10 may be folded in the first direction (X-axis direction). Accordingly, a length of the display device 10 in the first direction (X-axis direction) may be reduced by approximately half, and thus, a user may conveniently carry the display device 10.

An extension direction of the first folding line FOL1 and an extension direction of the second folding line FOL2 are not limited to the second direction (Y-axis direction). For example, the first folding line FOL1 and the second folding line FOL2 may extend in the first direction (X-axis direction), and the display device 10 may be folded in the second direction (Y-axis direction). A length of the display device 10 in the second direction (Y-axis direction) may be reduced by approximately half. In some embodiments, the first folding line FOL1 and the second folding line FOL2 may extend in a diagonal direction of the display device 10 corresponding to a direction between the first direction (X-axis direction) and the second direction (Y-axis direction). The display device 10 may be folded in a triangular shape.

When the first folding line FOL1 and the second folding line FOL2 extend in the second direction (Y-axis direction), a length of the folding area FDA in the first direction (X-axis direction) may be smaller than a length of the folding area FDA in the second direction (Y-axis direction). A length of the first non-folding area NFA1 in the first direction (X-axis direction) may be greater than the length of the folding area FDA in the first direction (X-axis direction). A length of the second non-folding area NFA2 in the first direction (X-axis direction) may be greater than the length of the folding area FDA in the first direction (X-axis direction).

A first display area DA1 may be disposed on a front surface of the display device 10. The first display area DA1 may overlap the folding area FDA, the first non-folding area NFA1, and the second non-folding area NFA2. Therefore, when the display device 10 is unfolded, an image may be displayed in a front surface direction in the folding area FDA, the first non-folding area NFA1, and the second non-folding area NFA2 of the display device 10.

A second display area DA2 may be disposed on a rear surface of the display device 10. The second display area DA2 may overlap the second non-folding area NFA2. Therefore, when the display device 10 is folded, an image may be displayed in a front surface direction in the second non-folding area NFA2 of the display device 10.

In FIGS. 14 and 15, a through hole TH in which a camera SDA or the like is formed is disposed in the first non-folding area NFA1, but the present disclosure is not limited thereto. A through hole TH or the camera SDA may be disposed in the second non-folding area NFA2 or the folding area FDA.

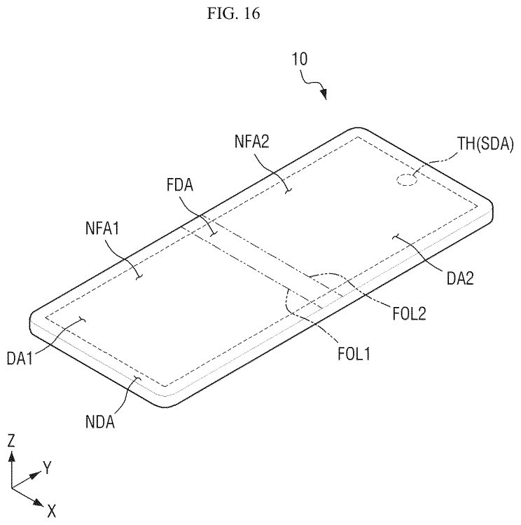

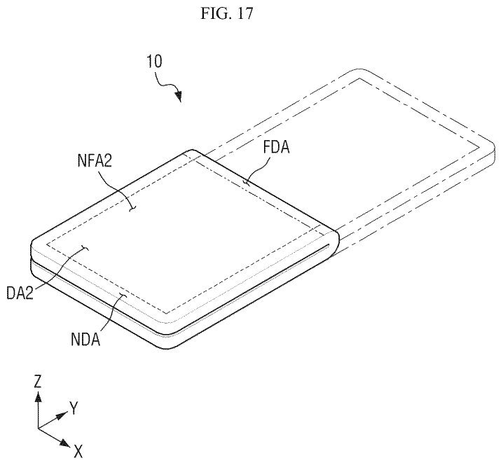

FIGS. 16 and 17 are perspective views illustrating a display device according to an embodiment of the present disclosure.

In FIGS. 16 and 17, a display device 10 is a foldable display device folded in the second direction (Y-axis direction). The display device 10 may be maintained in both a folded state and an unfolded state. The display device 10 may be folded in an in-folding manner in which a front surface thereof is disposed inside. When the display device 10 is bent or folded in the in-folding manner, front surfaces of the display device 10 may face each other. In some embodiments, the display device 10 may be folded in an out-folding manner in which a front surface thereof is disposed outside. When the display device 10 is bent or folded in the out-folding manner, rear surfaces of the display device 10 may face each other.

The display device 10 may include a folding area FDA, a first non-folding area NFA1, and a second non-folding area NFA2. The folding area FDA may be an area in which the display device 10 is folded, and the first non-folding area NFA1 and the second non-folding area NFA2 may be areas in which the display device 10 is not folded. The first non-folding area NFA1 may be disposed on one side, for example, the lower side of the folding area FDA. The second non-folding area NFA2 may be disposed on the other side, for example, on the upper side of the folding area FDA.

The touch sensing units TSU according to an embodiment of the present disclosure may be formed and disposed on the first non-folding area NFA1 and the second non-folding area NFA2, respectively.

On the other hand, the folding area FDA may be an area bent with a predetermined curvature in a first folding line FOL1 and a second folding line FOL2. Therefore, the first folding line FOL1 may be a boundary between the folding area FDA and the first non-folding area NFA1, and the second folding line FOL2 may be a boundary between the folding area FDA and the second non-folding area NFA2.

The first folding line FOL1 and the second folding line FOL2 may extend in the first direction (X-axis direction) as illustrated in FIGS. 16 and 17, and the display device 10 may be folded in the second direction (Y-axis direction). Accordingly, a length of the display device 10 in the second direction (Y-axis direction) may be reduced by approximately half, and thus, a user may conveniently carry the display device 10.

An extension direction of the first folding line FOL1 and an extension direction of the second folding line FOL2 are not limited to the first direction (X-axis direction).

For example, the first folding line FOL1 and the second folding line FOL2 may extend in the second direction (Y-axis direction), and the display device 10 may be folded in the first direction (X-axis direction). A length of the display device 10 in the first direction (X-axis direction) may be reduced by approximately half. In some embodiments, the first folding line FOL1 and the second folding line FOL2 may extend in a diagonal direction of the display device 10 corresponding to a direction between the first direction (X-axis direction) and the second direction (Y-axis direction). The display device 10 may be folded in a triangular shape.

When the first folding line FOL1 and the second folding line FOL2 extend in the first direction (X-axis direction) as illustrated in FIGS. 16 and 17, a length of the folding area FDA in the second direction (Y-axis direction) may be smaller than a length of the folding area FDA in the first direction (X-axis direction). A length of the first non-folding area NFA1 in the second direction (Y-axis direction) may be greater than the length of the folding area FDA in the second direction (Y-axis direction). A length of the second non-folding area NFA2 in the second direction (Y-axis direction) may be greater than the length of the folding area FDA in the second direction (Y-axis direction).

A first display area DA1 may be disposed on a front surface of the display device 10. The first display area DA1 may overlap the folding area FDA, the first non-folding area NFA1, and the second non-folding area NFA2. Therefore, when the display device 10 is unfolded, an image may be displayed in a front surface direction in the folding area FDA, the first non-folding area NFA1, and the second non-folding area NFA2 of the display device 10.

A second display area DA2 may be disposed on a rear surface of the display device 10. The second display area DA2 may overlap the second non-folding area NFA2. Therefore, when the display device 10 is folded, an image may be displayed in a front surface direction in the second non-folding area NFA2 of the display device 10.

In FIGS. 16 and 17, a through hole TH in which a camera SDA or the like is disposed is disposed in the second non-folding area NFA2, but the present disclosure is not limited thereto. The through hole TH may be disposed in the first non-folding area NFA1 or the folding area FDA.

In concluding the detailed description, those skilled in the art will appreciate that many variations and modifications can be made to the preferred embodiments without substantially departing from the principles of the present invention. Therefore, the disclosed preferred embodiments of the invention are used in a generic and descriptive sense only and not for purposes of limitation.

What is claimed is:

1. A display device comprising:
a plurality of unit pixels, wherein each unit pixel of the plurality of unit pixels includes a plurality of display pixels emitting respective lights and a light sensing pixel sensing light that is received from a front surface of the display device;
a plurality of touch electrodes configured to sense a touch on the front surface and, when viewed in a plan view, surrounding a first region where each of at least two display pixels is disposed and a second region where the light sensing pixel and one of the plurality of display pixels that is different from the at least two display pixels are disposed; and
a main driving circuit configured to:
receive light a sensing signal from the light sensing pixel; and
sense a fingerprint by analyzing the light sensing signal,
wherein the plurality of touch electrodes define at least one open area in which no touch electrode is formed between the light sensing pixel and at least one display pixel among the plurality of display pixels in each unit pixel of the plurality of unit pixels.

2. The display device of claim 1,
wherein the plurality of display pixels comprise first to third display pixels,
wherein the first to third display pixels comprise first to third emission areas, respectively, and the light sensing pixel comprises light sensing area, and
wherein the at least one open area corresponds to a space between the light sensing area and an emission area of the at least one display pixel in each unit pixel of the plurality of unit pixels.

3. The display device of claim 2,
wherein the first to third emission areas and the light sensing area are arranged in a horizontal structure, in a vertical stripe structure, or in a Pentile™ matrix structure,
wherein the plurality of touch electrodes comprise a plurality of driving electrodes, a plurality of sensing electrodes, and a plurality of dummy electrodes, and
wherein the plurality of driving electrodes, the plurality of sensing electrodes, and the plurality of dummy electrodes are formed in a mesh structure surrounding each of the first to third emission areas.

4. The display device of claim 3,
wherein at least one electrode of the plurality of driving electrodes, the plurality of sensing electrodes, and the plurality of dummy electrodes defines the at least one open area that corresponds to a space between the light sensing area and at least one emission area among the first to third emission areas in each unit pixel of the plurality of unit pixels.

5. The display device of claim 3,
wherein at least one electrode of the plurality of driving electrodes, the plurality of sensing electrodes, and the plurality of dummy electrodes is formed in a mesh structure when viewed in a plan view,
wherein the at least one open area corresponds to a space between the light sensing area of the light sensing pixel and an emission area of a second display pixel among the first to third display pixels,
wherein the second display pixel and the light sensing pixel are disposed in the second region, and
wherein the emission area of the second display pixel displays green light.

6. The display device of claim 5,
wherein the second display pixel is driven to emit the green light during a fingerprint sensing period, and
wherein the light sensing pixel is driven to sense light that is incident on the light sensing area from the front surface of the display device.

7. The display device of claim 3,
wherein at least one electrode of the plurality of driving electrodes, the plurality of sensing electrodes, and the plurality of dummy electrodes is formed in a mesh structure when viewed in a plan view,
wherein the at least one open area corresponds to a space between the light sensing area of the light sensing pixel and an emission area of the first display pixel among the first to third display pixels,
wherein the first display pixel and the light sensing pixel are disposed in the second region, and
wherein the emission area of the first display pixel displays red light.

8. The display device of claim 7,
wherein the first display pixel is driven to emit the red light during a fingerprint sensing period, and
wherein the light sensing pixel is driven to sense light that is incident on the light sensing area from the front surface of the display device.

9. The display device of claim 3,
wherein at least one electrode of the plurality of driving electrodes, the plurality of sensing electrodes, and the plurality of dummy electrodes is formed in a mesh structure when viewed in a plan view,
wherein the at least one open area corresponds to a space between the light sensing area of the light sensing pixel and an emission area of the third display pixel among the first to third display pixels,
wherein the third display pixel and the light sensing pixel are disposed in the second region, and
wherein the emission area of the third display pixel displays blue light.

10. The display device of claim 9,
wherein the third display pixel is driven to emit the blue light during a fingerprint sensing period, and
wherein the light sensing pixel is driven to sense light that is incident on the light sensing area from the front surface of the display device.

11. A display device comprising:
a plurality of unit pixels arranged in a horizontal stripe structure, in a vertical stripe structure, or in a Pentile™ matrix structure, wherein each unit pixel of the plurality of unit pixels includes first to third display pixels and a light sensing pixel;
a plurality of touch electrodes disposed above the first to third display pixels and the light sensing pixel to sense a touch; and
a main driving circuit for receiving a light sensing signal from the light sensing pixel to sense a fingerprint,
wherein the plurality of touch electrodes define at least one open area in which no touch electrode is formed in each unit pixel of the plurality of unit pixels, and
wherein, when viewed in a plan view, the at least one open area corresponds to a space between the light sensing pixel and at least one display pixel among the first to third display pixels in a region where each unit pixel of the plurality of unit pixels is formed.

12. The display device of claim 11,
wherein the first to third display pixels comprise first to third emission areas, respectively,
wherein the light sensing pixel comprises a light sensing area,
wherein the plurality of touch electrodes comprise a plurality of driving electrodes, a plurality of sensing electrodes, and a plurality of dummy electrodes, and
wherein the plurality of driving electrodes, the plurality of sensing electrodes, and the plurality of dummy electrodes are formed in a mesh structure surrounding the light sensing area.

13. The display device of claim 12,
wherein at least one electrode of the plurality of driving electrodes, the plurality of sensing electrodes, and the plurality of dummy electrodes defines the at least one open area that corresponds to a space between the light sensing area and at least one emission area among the first to third emission areas in each unit pixel of the plurality of unit pixels.

14. The display device of claim 12,
wherein the at least one open area corresponds to a space between the light sensing area and the second display pixel among the first to third display pixels, and
wherein the emission area of the second display pixel displays green light.

15. The display device of claim 14,
wherein the second display pixel is driven to emit the green light during a fingerprint sensing period, and
wherein the light sensing pixel is driven to sense light that is incident on the light sensing area from a front surface of the display device.
